(19) United States
(12) Patent Application Publication
(10) Pub. No.: US 2013/0253864 A1
(43) Pub. Date: Sep. 26, 2013

(54) Magnetic-Field Direction Measuring Apparatus, Rotation Angle Measuring Apparatus, and Magnetic-Field Measuring Apparatus

(71) Applicant: ASAHI KASEI MICRODEVICES CORPORATION, Tokyo (JP)

(72) Inventors: Taisuke Fujita, Tokyo (JP); Yoshihiko Watanabe, Tokyo (JP); Katsumi Kakuta, Tokyo (JP)

(73) Assignee: ASAHI KASEI MICRODEVICES CORPORATION, Tokyo (JP)

(21) Appl. No.: 13/845,638

(22) Filed: Mar. 18, 2013

(30) Foreign Application Priority Data
Mar. 22, 2012 (JP) 2012-065452
Apr. 24, 2012 (JP) 2012-098992
Jan. 15, 2013 (JP) 2013-004991

(51) Int. Cl. G01R 33/00

(52) U.S. Cl. CPC G01R 33/0005
USPC 702/65; 324/244; 324/207.13; 324/251

(57) ABSTRACT

The magnetic-field direction measuring apparatus includes a substantially rectangular rotation angle measuring chip, and a first magnetic field sensor and a second magnetic field sensor disposed substantially on a circumference centered around a predetermined point on a surface of the rotation angle measuring chip serving as a circle center point, the first magnetic field sensor detecting a magnetic component in a first direction, the second magnetic field sensor detecting a magnetic component in a second direction different from the first direction. The first magnetic field sensor and the second magnetic field sensor are positioned line-symmetrically with respect to a straight line on the surface of the substrate which is parallel to a longitudinal direction of the rotation angle measuring chip or a transverse direction of the rotation angle measuring chip and which serves as an axis of symmetry.

### CROSS-REFERENCES TO RELATED APPLICATIONS

This application claims the benefit of Japanese Patent Application Nos. 2012-098992 filed on Apr. 24, 2012, 2012-065452 filed on Mar. 22, 2012 and 2013-004991 filed on Jan. 15, 2013, which are hereby incorporated by reference herein in their entirety.

### BACKGROUND OF THE INVENTION

1. Field of the Invention

The present invention relates to a magnetic-field direction measuring apparatus, a rotation angle measuring apparatus, and a magnetic-field measuring apparatus which measure the magnitude or direction of a magnetic field based on an output from a magnetic field sensor that detects a magnetic component.

2. Description of the Related Art

A magnetic-field direction measuring apparatus that measures the direction of a magnetic field is used in every aspect of daily life. For example, a steering is provided in a vehicle as an apparatus for changing the direction of the vehicle during traveling. In this case, to control rotation of the steering and tires, a rotation angle measuring apparatus that measures a rotation angle is used. The rotation angle measuring apparatus is a type of magnetic-field direction measuring apparatus and transduces the detected direction of a magnetic field into a rotation angle and outputs the rotation angle.

A conventional method for measuring the direction of a magnetic field is to detect a magnetic field parallel to a surface of a sensor chip using a Hall element that is a magnetic field sensor and a magnetic flux concentrator.

FIG. 1 is a diagram illustrating a rotation angle measuring chip 51 according to a conventional technique (WO 03/081182). In a central portion of a surface of the rectangular rotation angle measuring chip 51, a circular magnetic flux concentrator 7 formed of, for example, a soft magnetic thin film is provided. On the surface of the rotation angle measuring chip 51, a circle center point 9 is provided which is an intersection point between the rotation angle measuring chip 51 and a rotation axis of the magnetic flux concentrator 7. On the circumference of a circle centered around the circle center point 9 and having a radius similar to the radius of the magnetic flux concentrator 7 in length, X axis Hall elements 53a and 53b and Y axis Hall elements 55a and 55b are installed point-symmetrically with respect to the circle center point 9.

That is, two line segments joining the X axis Hall elements 53 together and the Y axis Hall elements 55 together, respectively, are parallel to a transverse direction and a longitudinal direction, respectively, of the rotation angle measuring chip 51. The two line segments intersect at the circle center point 9. Moreover, the distance from the circle center point 9 to the X axis Hall element 53a is equal to the distance from the circle center point 9 to the X axis Hall element 53b. The distance from the circle center point 9 to the Y axis Hall element 55a is equal to the distance from the circle center point 9 to the Y axis Hall element 55b. Here, the direction from the X axis Hall element 53b toward the X axis Hall element 53a and the direction from the Y axis Hall element 55b toward the Y axis Hall element 55a are defined to be a positive direction of the X axis and a positive direction of the Y axis, respectively.

In FIG. 1, when a magnetic field 57 is applied to the rotation angle measuring chip 51, output differential voltages V (X+), V (X−), V (Y+), and V (Y−) from the Hall elements 53a, 53b, 55a, and 55b are sine wave voltages and cosine wave voltages in accordance with:

V(X+)=A1×cos θ

V(X−)=−A2×cos θ.

V(Y+)=A3×sin θ

V(Y−)=−A4×sin θ (1).

Here, proportional constants A1, A2, A3, and A4 are used, and a counterclockwise angle (magnetic-field application angle) θ is subtended between the X axis direction and the direction of the magnetic field 57 in FIG. 1. The differences between the output voltages are determined as expressed by Expression 2 to derive output voltages Vx and Vv in the X axis direction and the Y axis direction.

Vx=V(X+)−V(X−)=(A1+A2)×cos θ

Vy=V(Y+)−V(Y−)=(A3+A4)×sin θ (2)

The output voltages Vx and Vy are used to calculate a rotation angle.

Specifically, on the assumption that the Hall elements 53a, 53b, 55a, and 55b have equal output characteristics, that is, A1=A2=A3=A4, the rotation angle can be calculated in accordance with:

$$\begin{matrix}Vy / Vx = \{ ( A 3 + A 4 ) \times sin θ \} / \{ ( A 1 + A 2 ) \times cos θ \} \\ = \{ ( A 3 + A 4 ) / ( A 1 + A 2 ) \} \times tan θ .\end{matrix}$$

Here, given that A1=A2=A3=A4, the following holds true.

θ=arctan(Vy/Vx) (3)

### SUMMARY OF THE INVENTION

An apparatus that requires the difference between or the ratio of outputs from a plurality of magnetic field sensors expects that the plurality of magnetic field sensors provides the same output under the same magnetic field conditions. That is, a magnetic sensitivity that is a proportional constant for the magnetic field and the output from each of the magnetic field sensors is expected to be the same among the plurality of magnetic field sensors. Furthermore, when the magnetic field sensors have offsets, even if a plurality of Hall elements has the same offset, the Hall elements output ratio varies. Thus, the value of the offset is expected to be as small as possible.

The magnetic sensitivity and offset of the magnetic field sensor change when the magnetic field sensor is mechanical stressed. If the magnetic field sensor is a Hall element, a piezo Hall effect or a piezoresistance effect accounts for the change in magnetic sensitivity and offset caused by the mechanical stress.

Moreover, even when the same mechanical stress is applied to a plurality of Hall elements, if the relation between the driving direction of each Hall element and the crystal orientation of silicon varies, the amount of change caused by the mechanical stress varies.

Thus, in order to increase the accuracy of the apparatus requiring the difference between or the ratio of the outputs from the plurality of Hall elements, the mechanical stresses applied to the Hall elements need to be made uniform and the relation between the driving direction of each Hall element and the crystal orientation of silicon needs to be optimized.

In view of these circumstances, it is an object of the present invention to provide a magnetic-field direction measuring apparatus, a rotation angle measuring apparatus, and a magnetic-field measuring apparatus in which magnetic field sensors are arranged so as to be restrained from being affected by mechanical stress.

To accomplish this object, an aspect of the present invention provides a magnetic-field direction measuring apparatus according to the present invention including a substantially rectangular substrate and at least one first magnetic field sensor and at least one second magnetic field sensor disposed substantially on a circumference centered around a predetermined point on a surface of the substrate serving as a circle center point, the first magnetic field sensor detecting a magnetic component in a first direction, the second magnetic field sensor detecting a magnetic component in a second direction different from the first direction, the magnetic-field direction measuring apparatus measuring a direction of a magnetic field based on intensities of output signals from the first magnetic field sensor and the second magnetic field sensor, wherein the first magnetic field sensor and the second magnetic field sensor are positioned line-symmetrically with respect to a straight line on the surface of the substrate which is parallel to a longitudinal direction of the substrate or a transverse direction of the substrate and which serves as an axis of symmetry.

This configuration allows mechanical stresses applied to the first magnetic field sensor and the second magnetic field sensor to be made almost equal, enabling the coefficients of intensities of output signals from the first magnetic field sensor and the second magnetic field sensor to be made equal. Thus, the magnetic-field direction can be accurately measured.

Moreover, in the magnetic-field direction measuring apparatus according to the present invention, the first magnetic field sensor and the second magnetic field sensor may be positioned line-symmetrically with respect to a straight line which is parallel to the longitudinal direction of the substrate or the transverse direction of the substrate and which passes through a center of the surface of the substrate, the straight line serving as an axis of symmetry.

This configuration allows the mechanical stresses applied to the first magnetic field sensor and the second magnetic field sensor positioned line-symmetrically to be made more uniform, enabling the magnetic-field direction to be more accurately measured.

Another aspect of the present invention is a rotation angle measuring apparatus including a substantially rectangular substrate, a rotator having a rotation axis perpendicular to a surface of the substrate and generating a magnetic field, and at least one first magnetic field sensor and at least one second magnetic field sensor disposed on a surface of the substrate and substantially on a circumference centered around a position of an intersection point between the surface of the substrate and the rotation axis, the position serving as a circle center point, the first magnetic field sensor detecting a magnetic component in a first direction, the second magnetic field sensor detecting a magnetic component in a second direction different from the first direction, the rotation angle measuring apparatus measuring a rotation angle of the rotator based on intensities of output signals from the first magnetic field sensor and the second magnetic field sensor, wherein the first magnetic field sensor and the second magnetic field sensor are positioned line-symmetricaly with respect to a straight line on the surface of the substrate which is parallel to a longitudinal direction of the substrate or a transverse direction of the substrate, the straight line serving as an axis of symmetry.

This configuration allows mechanical stresses applied to the first magnetic field sensor and the second magnetic field sensor to be made almost equal, enabling the coefficients of intensities of output signals from the first magnetic field sensor and the second magnetic field sensor to be made equal. Thus, the rotation angle can be accurately measured.

Moreover, in the rotation angle measuring apparatus according to the present invention, the first magnetic field sensor and the second magnetic field sensor may be positioned line-symmetrically with respect to a straight line which is parallel to the longitudinal direction of the substrate or the transverse direction of the substrate and which passes through a center of the surface of the substrate, the straight line serving as an axis of symmetry.

This configuration allows the mechanical stresses applied to the first magnetic field sensor and the second magnetic field sensor positioned line-symmetrically to be made more uniform, enabling the rotation angle to be more accurately measured.

Another aspect of the present invention provides a magnetic-field measuring apparatus including a substantially rectangular silicon substrate, at least one Hall element formed on a surface of the silicon substrate and having a first terminal pair and a second terminal pair each including two terminals provided at opposite directions, an axis of the first terminal pair being orthogonal to an axis of the second terminal pair, and a magnetic flux concentrator provided on the surface of the silicon substrate,

wherein crystal orientations of the silicon substrate in a longitudinal direction and a transverse direction thereof are equivalent to <110>,

when the silicon substrate and the magnetic flux concentrator are viewed in plane, the axis of the first terminal pair of the Hall element is parallel to a tangential direction, on an outer edge of the magnetic flux concentrator, of a tangent point between the outer edge of the magnetic flux concentrator and a minimum-radius circle centered around a center of the Hall element serving as a circle center point, and

the Hall element is formed on the surface of the silicon substrate in such a manner that the axis of the first terminal pair subtends an angle of 45° to the longitudinal direction or the transverse direction of the silicon substrate.

This configuration takes the positional relations between the Hall element and the substrate and the magnetic flux concentrator to enable a reduction in an offset voltage caused by a difference between a coefficient of piezoresistance in a longitudinal direction of piezoresistors in the Hall element modeled by a Wheatstone bridge circuit of piezoresistance elements and a coefficient of piezoresistance in a transverse direction of the piezoresistors, and an offset voltage caused by a difference in mechanical stress applied to the Hall element by the magnetic flux concentrator.

Moreover, the magnetic-field measuring apparatus takes into account a relation for the offset voltage generated in the Hall element expressed by:

Voffset=r0·(π_{L}−π_{T})·(σx−σy)·I/2.

(a current I flows through the Hall element, a piezoresistance value r0 is obtained when no mechanical stress is applied to the Hall element, a coefficient of piezoresistance π_{L} is intended for the longitudinal direction, a coefficient of piezoresistance π_{T} is intended for the transverse direction, and one of mechanical stresses σx and σy is applied to the piezoresistors in the longitudinal direction thereof, and the other is applied to the piezoresistors in the transverse direction thereof), and

in order to reduce the offset voltage caused by the difference in the coefficient of piezoresistance of the piezoresistor, the Hall element may be disposed to decrease the difference between the coefficient of piezoresistance in the longitudinal direction of the piezoresistors between the terminal pairs and the coefficient of piezoresistance in the transverse direction of the piezoresistors, and in order to reduce the offset voltage caused by the difference in mechanical stress applied by the magnetic flux concentrator, the Hall element may be disposed parallel to an edge of the Magnetic flux concentrator to decrease the difference between the mechanical stress applied to the piezoresistors in the longitudinal direction thereof and the mechanical stress applied to the piezoresistors in the transverse direction thereof.

Moreover, in the magnetic-field measuring apparatus according to the present invention, when the silicon substrate and the magnetic flux concentrator are viewed in plane, the magnetic flux concentrator may appear to be shaped line-symmetrically with respect to the axis of the second terminal pair serving as an axis of symmetry.

In the magnetic-field measuring apparatus according to the present invention, the magnetic flux concentrator may be shaped like one of a circle, a polygon, an ellipse, and a semicircle.

Moreover, in the magnetic-field measuring apparatus according to the present invention, arithmetic processing may be carried out to convert an output from the Hall element into an output based on a direction parallel to the longitudinal direction or transverse direction of the silicon substrate.

Furthermore, another aspect of the present invention provides a magnetic-field measuring apparatus including a substrate with a predetermined crystal orientation, a Hall element provided on the substrate, and a magnetic flux concentrator provided on the Hall element in such a manner that the Hall element is disposed at an end of the substrate,

the Hall element has a first terminal pair and a second terminal pair each including two terminals provided at opposite positions,

the magnetic-field measuring apparatus takes into account a relation for the offset voltage generated in the Hall element expressed by:

Voffset=r0·(π_{L}−π_{T})·(σx−σy)·I/2.

(a current I flows through the Hall element, a piezoresistance value 3:0 is obtained when no mechanical stress is applied to the Hall element, a coefficient of piezoresistance π_{T} is intended for a longitudinal direction, a coefficient of piezoresistance π_{T} intended for a transverse direction, and one of mechanical stresses σx and σy is applied to piezoresistors in the longitudinal direction thereof, and the other is applied to the piezoresistors in the transverse direction thereof),

in order to reduce an offset voltage caused by a difference in the coefficient of piezoresistance of the piezoresistor, the Hall element is disposed to decrease a difference between the coefficient of piezoresistance in the longitudinal direction of the piezoresistors between the terminal pairs and the coefficient of piezoresistance in the transverse direction of the piezoresistors, and in order to reduce an offset voltage caused by a difference in mechanical stress applied by the magnetic flux concentrator, the Hall element is disposed parallel to an edge of the magnetic flux concentrator to decrease a difference between a mechanical stress applied to the piezoresistors in the longitudinal direction thereof and a mechanical stress applied to the piezoresistors in the transverse direction thereof.

This configuration takes the positional relation between the Hall element and the substrate and the magnetic flux concentrator to enable a reduction in the offset voltage caused by the difference between the coefficient of piezoresistance in the longitudinal direction of the piezoresistors of the Hall element modeled by a Wheatstone bridge circuit of piezoresistance elements and the coefficient of piezoresistance in the transverse direction of the piezoresistors, and the offset voltage caused by the difference in the mechanical stress applied to the Hall element by the magnetic flux concentrator.

As described above, the aspects of the present invention can provide a magnetic-field direction measuring apparatus, a rotation angle measuring apparatus, and a magnetic-field measuring apparatus in which magnetic field sensors are arranged so as to be restrained from being affected by mechanical stress.

Further features of the present invention will become apparent from the following description of exemplary embodiments (with reference to the attached drawings).

### BRIEF DESCRIPTION OF THE DRAWINGS

FIG. 1 is a diagram illustrating a conventional rotation angle measuring chip;

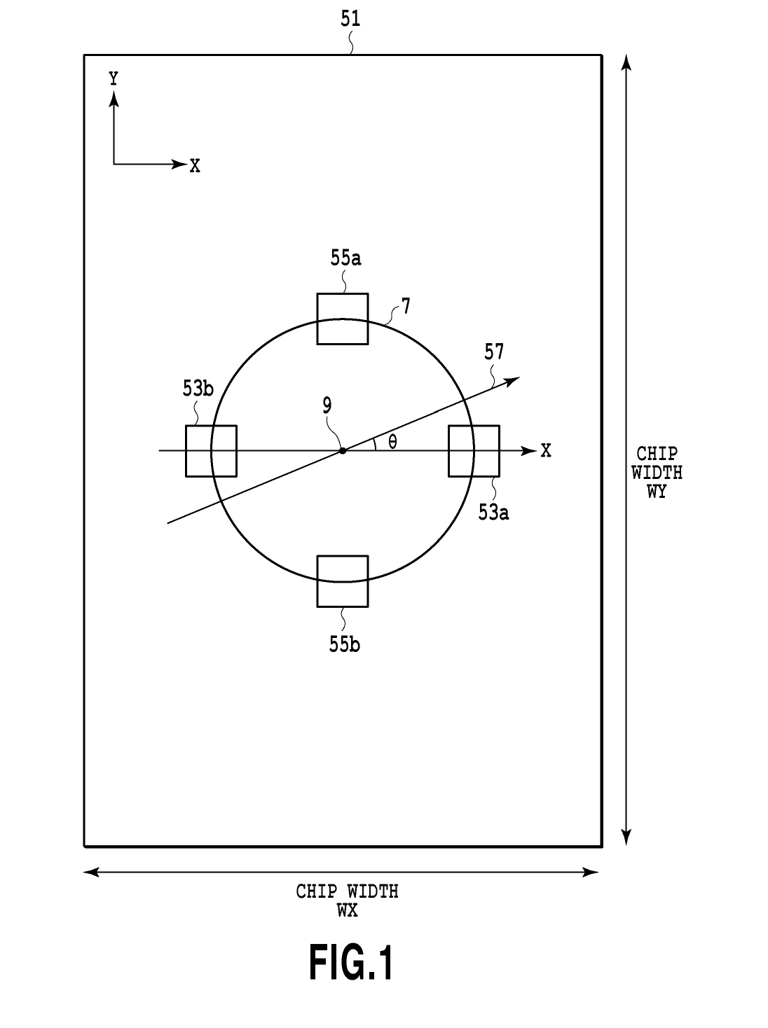

FIG. 2 is a bottom view illustrating a rotation angle measuring apparatus using a rotation angle measuring chip according to the present embodiment;

FIG. 3 is a cross-sectional view illustrating the rotation angle measuring apparatus using the rotation angle measuring chip according to the present embodiment;

FIG. 4 is a diagram illustrating a rotation angle measuring chip according to Embodiment 1;

FIG. 5 is a side view illustrating the rotation angle measuring apparatus using the rotation angle measuring chip according to the present embodiment;

FIG. 6 is a diagram showing a comparison between an output signal from a Hall element obtained in a normal state and an output signal from the Hall element obtained when an error has occurred;

FIG. 7 is a diagram showing a comparison between the output signal from the Hall element obtained in the normal state and the output signal from the Hall element obtained when an error has occurred;

FIG. 8 is a diagram showing the shape of the rotation angle measuring chip and a mechanical stress measurement position;

FIG. 9 is a diagram showing relations between a measurement position and mechanical stress;

FIG. 10 is a diagram illustrating a rotation angle measuring chip according to Embodiment 2;

FIG. 11 is a diagram illustrating a rotation angle measuring chip according to Embodiment 3;

FIG. 12 is a diagram illustrating the rotation angle measuring chip according to Embodiment 3;

FIG. 13 is a diagram illustrating a rotation angle measuring chip according to Embodiment 4;

FIG. 14 is a diagram showing that an angle θ is subtended between an X axis and a Y axis;

FIG. 15 is a diagram illustrating a rotation angle measuring chip according to Embodiment 5;

FIG. 16 is a diagram showing an arrangement of conventional Hall elements compared with the arrangement in Embodiment 5;

FIG. 17 is a diagram showing an arrangement of a magnetic flux concentrator and Hall elements on a conventional rotation angle measuring chip;

FIG. 18 is a cross-sectional view of a rotation angle measuring apparatus using the conventional rotation angle measuring chip;

FIG. 19 is a diagram illustrating a comparison of mechanical stresses exerted in a longitudinal direction and a transverse direction of the conventional rotation angle measuring chip;

FIG. 20 is a diagram illustrating a comparison of the mechanical stresses exerted in the longitudinal direction and transverse direction of the conventional rotation angle measuring chip;

FIG. 21 is a diagram illustrating a comparison of the mechanical stresses exerted in the longitudinal direction and transverse direction of the conventional rotation angle measuring chip;

FIG. 22 is a diagram showing a mechanical stress ratio between a mechanical stress on an X axis and a mechanical stress on a Y axis which are located at an equal distance from the center of the conventional rotation angle measuring chip;

FIG. 23 is a circuit diagram showing a conventional magnetic sensor with the impact of an offset voltage reduced;

FIG. 24A and FIG. 24B are diagrams showing a bridge circuit of piezoresistors included in a Hall element in a magnetic-field measuring apparatus according to the present invention;

FIG. 25 is a diagram showing a relation between a coefficient of piezoresistance in the longitudinal direction of the piezoresistors and a coefficient of piezoresistance for a direction (transverse direction) perpendicular to the longitudinal direction, with respect to a crystal orientation <110> of an Si substrate;

FIG. 26 is a diagram showing a bridge circuit and illustrating relations between mechanical stress and offset in the Hall element in the magnetic-field measuring apparatus according to the present invention;

FIG. 27A and FIG. 27B are diagrams showing results of simulation of temperature characteristics of a first mechanical stress and a second mechanical stress exerted when a terminal pair of the Hall element is disposed parallel or perpendicularly to an edge of the magnetic flux concentrator and when the terminal pair is disposed at an angle of 45° to the edge of the magnetic flux concentrator;

FIG. 28 is a diagram showing a bridge circuit and illustrating relations between mechanical stress and offset in the Hall element in the magnetic-field measuring apparatus according to the present invention;

FIG. 29 is a configuration diagram illustrating Embodiment 6 of the magnetic-field measuring apparatus according to the present invention;

FIG. 30 is a configuration diagram illustrating a tangential direction in FIG. 29 and showing a variation of Embodiment 6;

FIG. 31 is a configuration diagram showing a further variation of Embodiment 6 shown in FIG. 29;

FIG. 32 is a configuration diagram showing further another variation of Embodiment 6 shown in FIG. 29;

FIG. 33 is a diagram illustrating that arithmetic processing is carried out to transduce an output from the Hall element into an output based on a direction parallel to sides of the silicon substrate;

FIG. 34 is a configuration diagram illustrating Embodiment 7 of the magnetic-field measuring apparatus according to the present invention;

FIG. 35 is a diagram illustrating a tangential direction in FIG. 34;

FIG. 36 is a configuration diagram illustrating Embodiment 8 of the magnetic-field measuring apparatus according to the present invention; and

FIG. 37 is a diagram illustrating a tangential direction in FIG. 36.

### DESCRIPTION OF THE EMBODIMENTS

Embodiments of the present invention will be described below with reference to the drawings.

### Embodiment 1

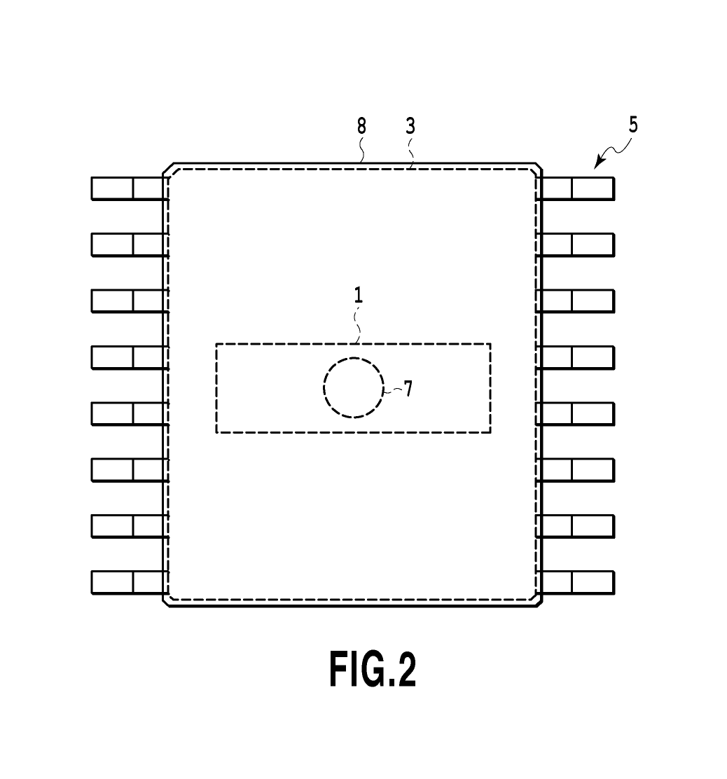

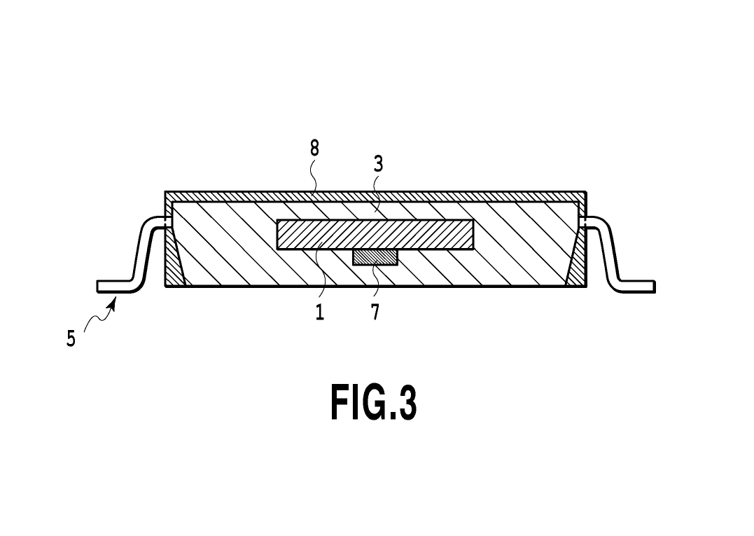

FIG. 2 and FIG. 3 are a bottom view and a cross-sectional view illustrating a rotation angle measuring apparatus using a rotation angle measuring chip 1 according to the present invention. In FIG. 2 and FIG. 3, a rectangular chip mounted substrate 3 on which the rectangular rotation angle measuring chip 1 is installed includes a plurality of terminals 5 connected to opposite side surfaces of the substrate 3 in a longitudinal direction thereof. The rotation angle measuring chip 1, having a longitudinal direction perpendicular to the longitudinal direction of the substrate 3, is installed on a surface of the substrate 3 in a central portion thereof. A disc-shaped magnetic flux concentrator 7 is installed on the surface of the rotation angle measuring chip 1 in the central portion thereof. Moreover, the chip mounted substrate 3 is entirely covered with a resin mold 8.

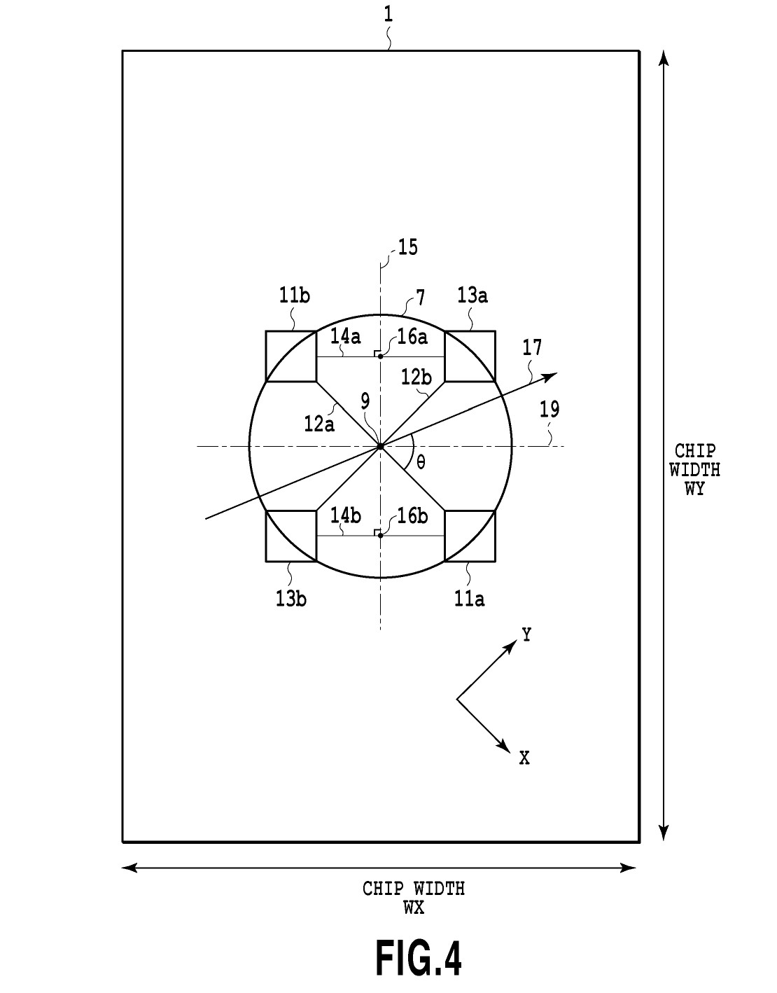

FIG. 4 is a diagram illustrating the rotation angle measuring chip 1 according to Embodiment 1 of the present invention. A circle center point 9 that is an intersection point between the rotation angle measuring chip 1 and a rotation axis of a rotator is provided on the surface of the rotation angle measuring chip 1. On the circumference of a circle centered around the circle center point 9 and having a radius similar to the radius of the magnetic flux concentrator, X axis Hall elements 11a and 11b and Y axis Hall elements 13a and 13b are installed point-symmetrically with respect to the circle center point 9. That is, two line segments 12a and 12b joining the X axis Hall elements 11 together and the Y axis Hall elements 13 together, respectively, intersect at the circle center point 9. Moreover, the distance from the circle center point 9 to the X axis Hall element 11a is equal to the distance from the circle center point 9 to the X axis Hall element 11b. The distance from the circle center point 9 to the Y axis Hall element 13a is equal to the distance from the circle center point 9 to the Y axis Hall element 13b.

In addition, the X axis Hall element 11a and the Y axis Hall element 13b are positioned line-symmetrically with respect to an axis of symmetry 15 which passes through the circle center point 9 and which is parallel to the longitudinal direction of the rotation angle measuring chip 1. The X axis Hall element 11b and the Y axis Hall element 13a are also positioned line-symmetrically with respect to the axis of symmetry 15. That is, line segments 14a and 14b joining the X axis Hall element 11a and the Y axis Hall element 13b together and the X axis Hall element 11b and the Y axis Hall element 13a together, respectively, are each orthogonal to the axis of symmetry 15. Moreover, an intersection point between the line segment 14a and the axis of symmetry 15 is referred to as an intersection point 16a. An intersection point between the line segment 14b and the axis of symmetry 15 is referred to as an intersection point 16b. In this case, the distance from the intersection point 16a to the X axis Hall element 11b is equal to the distance from the intersection point 16a to the Y axis Hall element 13a. Furthermore, the distance from the intersection point 16b to the X axis Hall element 11a is equal to the distance from the intersection point 16b to the axis Hall element 13b. Here, the direction from the X axis Hall element 11b toward the X axis Hall element 11a and the direction from the Y axis Hall element 13b toward the Y axis Hall element 13a are defined to be a positive direction of the X axis and a positive direction of the Y axis, respectively.

A method for detecting the rotation angle will be described with reference to FIG. 4. When a magnetic field 17 is applied as shown in FIG. 4, output differential voltages V(X+), V(X−), V(Y+), and V(Y−) from the Hall elements 11a, 11b, 13a, and 13b are such sine wave voltages and cosine wave voltages as expressed by:

V(X+)=A1×cos θ

V(X−)=−A2×cos θ.

V(Y+)=A3×sin θ

V(Y−)=−A4×sin θ (4).

Here, proportional constants A1, A2, A3, and A4 are used, and a counterclockwise angle (magnetic-field application angle) θ is subtended between the X axis direction and the direction of the magnetic field 17 in FIG. 4.

In this case, the Hall elements 11b and 13a are positioned line-symmetrically with respect to the axis of symmetry 15, and thus, substantially the same mechanical stress is applied to the Hall elements 11b and 13a. Consequently, A2=A3. Similarly, the Hall elements 11a and 13b are positioned line-symmetrically with respect to the axis of symmetry 15, and thus, substantially the same mechanical stress is applied to the Hall elements 11a and 13b. Consequently, A1=A4. As a result, Expression (4) can be approximated to:

V(X+)=A1×cos θ

V(X−)=−A2×cos θ.

V(Y+)=A2×sin θ

V(Y−)=−A1×sin θ (4)′.

The differences between the output voltages are determined as expressed by Expression (5) to derive output voltages Vx and Vy in the X axis direction and the Y axis direction.

Vx=V1(X+)−V2(X−)=(A1+A2)×cos θ

Vy=V1(Y+)−V2(Y−)=(A1+A2)×sin θ (5)

The output voltages Vx and Vy generated are used to calculate a relative angle.

Signal processing is carried out as follows. Two magnetic field sensors detect a magnetic field on two axes crossing at right angles around the rotation axis, and output two types of sine wave signals with different phases. If the sine wave signals have a sine-cosine relation, the rotation angle can be calculated by carrying out a division as expressed by Expression (6) to determine an arc tangent.

tan θ=Vy/Vx

∴=arctan(Vx/Vy) (6)

Thus, disposing the Hall elements as in Embodiment 1 allows the impact of the mechanical stress applied to each Hall element to be mitigated. As a result, the coefficient of the output voltage in the X axis direction is equal to the coefficient of the output voltage in the Y axis direction, enabling a reduction in angular error. This enables a reduction in errors in angle detection, allowing the rotation angle to be accurately detected.

Moreover, in Embodiment 1, the X axis Hall element 11a and the Y axis Hall element 13a can be disposed line-symmetrically with respect to an axis of symmetry 19 which passes through the circle center point 9 and which is parallel to the transverse direction of the rotation angle measuring chip 1. The X axis Hall element 11b and the Y axis Hall element 13b can also be disposed line-symmetrically with respect to the axis of symmetry 19. That is, the line segment joining the X axis Hall elements together and the line segment joining the Y axis Hall elements together can be set to cross at right angles at the circle center point 9. Thus, the output voltage in the X axis direction can be set equal to the output voltage in the Y axis direction, allowing the rotation angle to be more accurately detected.

Either the X axis Hall element 11b and the Y axis Hall element 13a or the X axis Hall element 11a and the Y axis Hall element 13b may be exclusively used. However, the impact of offset can be reduced by using a plurality of X axis Hall elements and a plurality of Y axis Hall elements. Furthermore, the axes of symmetry 15 and 19 for line symmetry are not limited to axes passing through a central portion of the rotation angle measuring chip but may be displaced from the central portion.

However, mechanical stresses generated in the chip are mostly line-symmetric with respect to a straight line which is parallel to the longitudinal direction of the chip and which passes through the central portion of the chip and further with respect to a straight line which is parallel to the transverse direction of the chip and which passes through the central portion of the chip. Thus, to make the mechanical stresses on the X axis Hall elements and the Y axis Hall elements more uniform, the axes of symmetry 15 and 19 are preferably straight lines passing through the central portion of the rotation angle measuring chip.

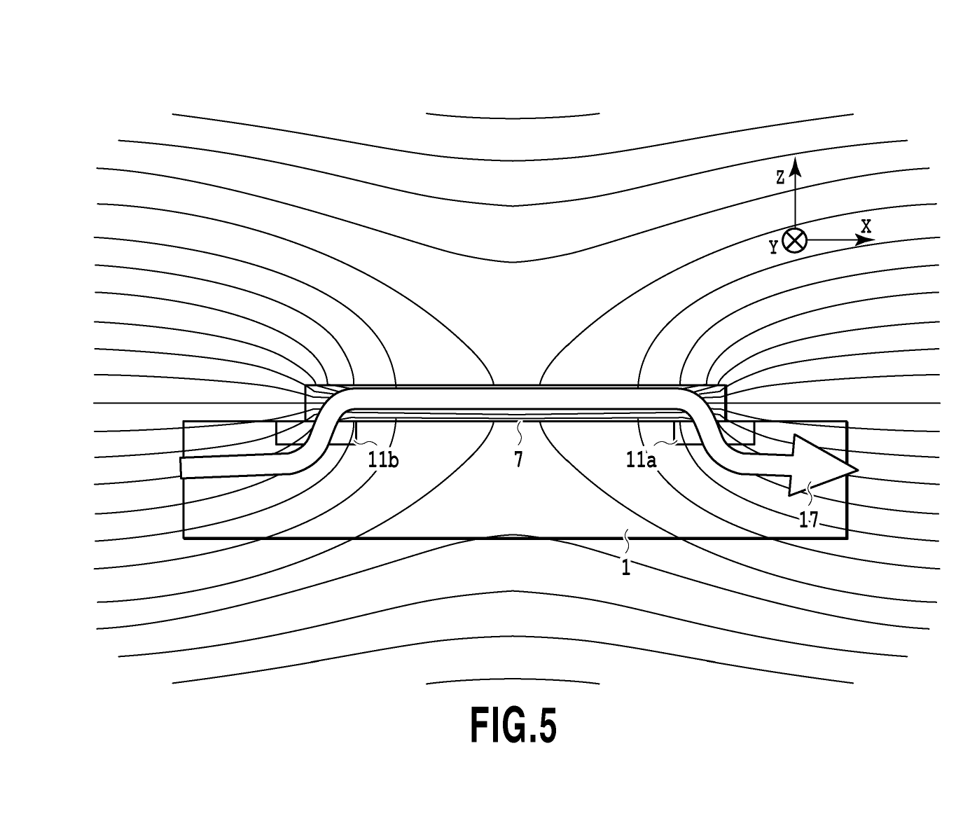

FIG. 5 shows lines of magnetic force obtained during application of a magnetic field 17 that is horizontal with respect to the X axis direction when the rotation angle measuring chip 1 according to Embodiment 1 is used to detect the rotation angle. The magnetic flux concentrator 7 transduces the horizontal magnetic field 17 into a magnetic field 17 which is perpendicular to a Hall element sensing surface and which can be sensed by the Hall elements 11a and 11b.

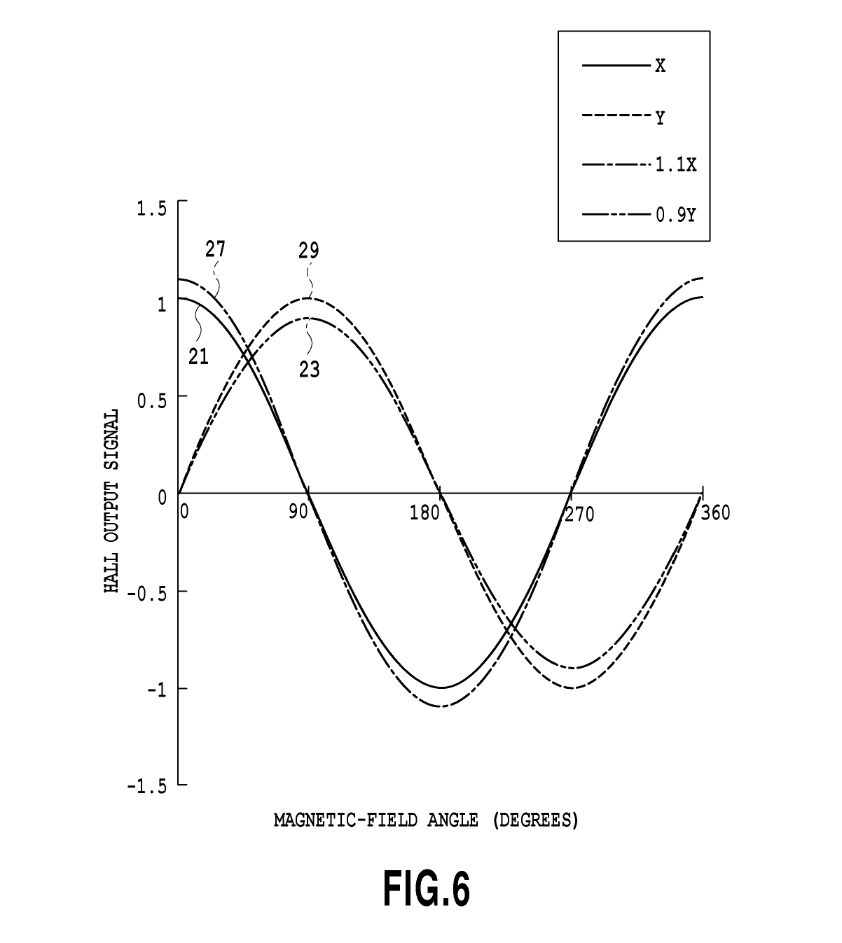

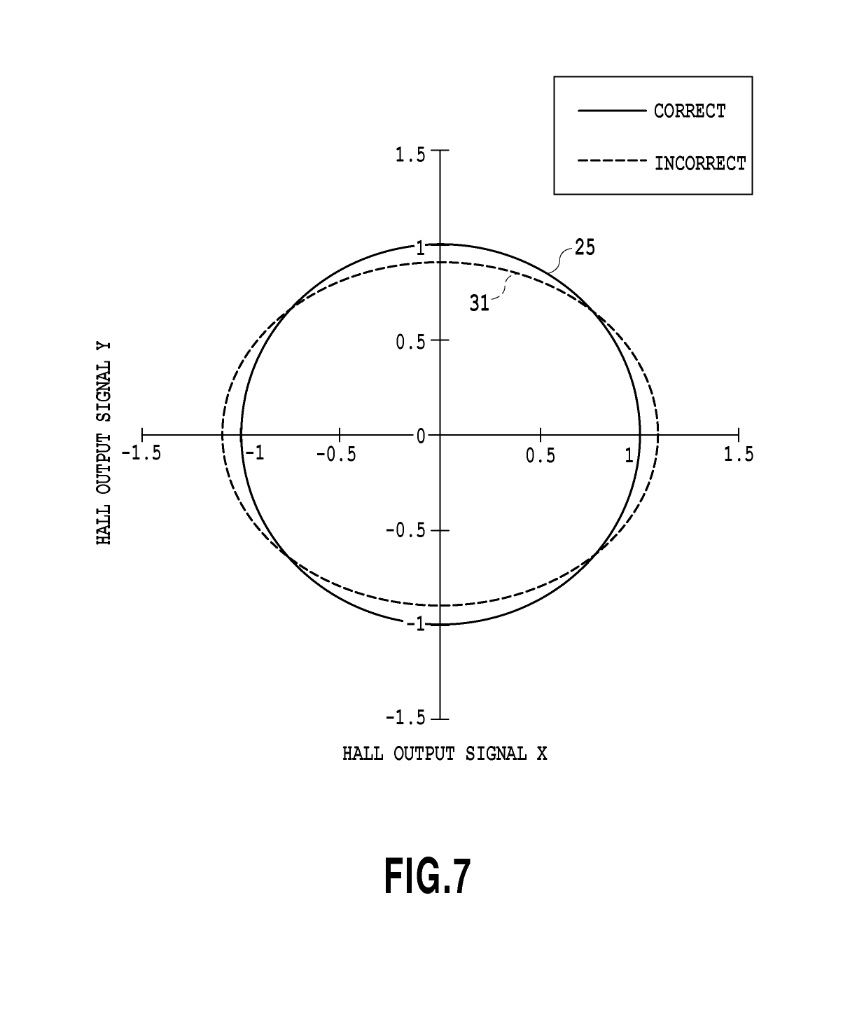

FIG. 6 and FIG. 7 are diagrams showing a comparison between an output signal from the Hall element obtained in a normal state and an output signal from the Hall element obtained when an error has occurred. In FIG. 6, when the output signal intensity is equal in the X and Y axis directions as in the case of an output signal intensity 21 in the X axis direction and an output signal intensity 29 in the Y axis direction, a circular waveform 25 is obtained which corresponds to the normal state in FIG. 7. However, in FIG. 6, if an angular error occurs as in the case of an output signal intensity 27 in the X axis direction and an output signal intensity 23 in the Y axis direction, an elliptic waveform 31 obtained which corresponds to the occurrence of an error. As described above, Embodiment I can reduce angular errors to accurately detect the rotation angle.

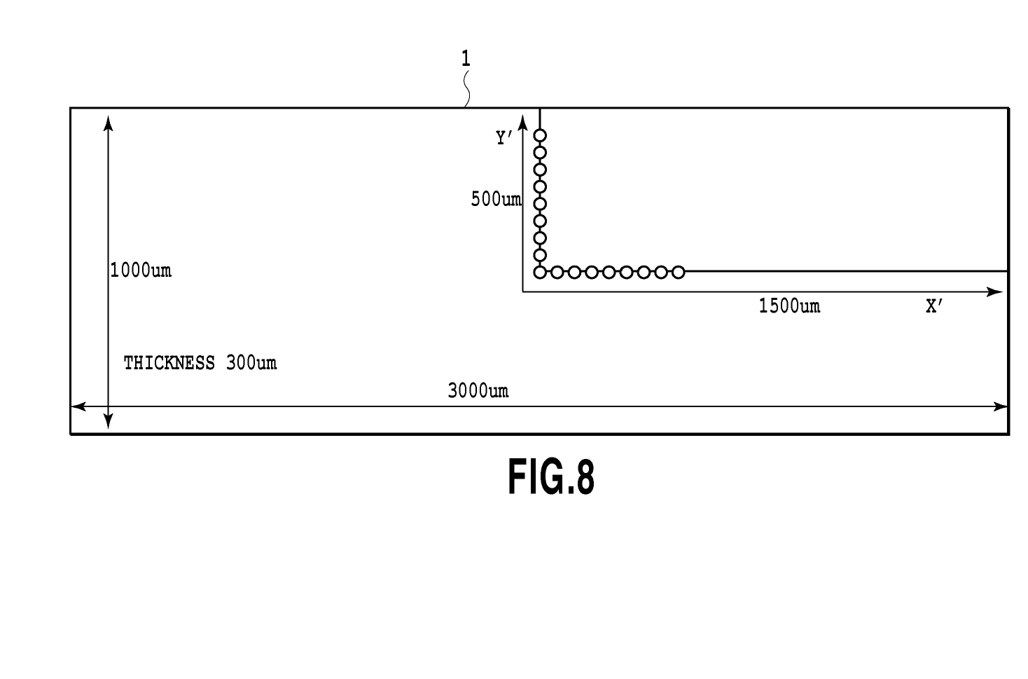

FIG. 8 is a diagram showing the shape of the rotation angle measuring chip 1 and a mechanical stress measurement position. The longitudinal direction of the rotation angle measuring chip 1 corresponds to an X′ axis direction. The transverse direction of the rotation angle measuring chip 1 corresponds to a Y′ axis direction. The mechanical stress applied to the surface of the rotation angle measuring chip 1 is expected to vary between the center and each end of the rotation angle measuring chip 1 due to the thickness of a package resin such as the resin mold 8 for the magnetic flux concentrator 7, a difference in the coefficient of thermal expansion between the package resin and the chip, cutout of the substrate, or the like. Moreover, for the above-described reason, a mechanical stress positioned a length L away from the center in the X′ axis direction is significantly different from a mechanical stress positioned the length L away from the center in the X′ axis direction. Even mechanical stresses present at an equal distance from the center may differ significantly from each other depending on coordinate values in the X′ axis direction and the Y′ axis direction.

The difference in mechanical stress also occurs when the rotation angle measuring chip 1 is shaped like a square. This tendency is particularly significant if the rotation angle measuring chip 1 is shaped like a rectangle in which one side is longer than the other side. Thus, the longitudinal direction of the rotation angle measuring chip 1 is defined to be the X′ axis direction, and the transverse direction of the rotation angle measuring chip 1 is defined to be the Y′ axis direction. The relations between the mechanical stress and the distance from the center are measured.

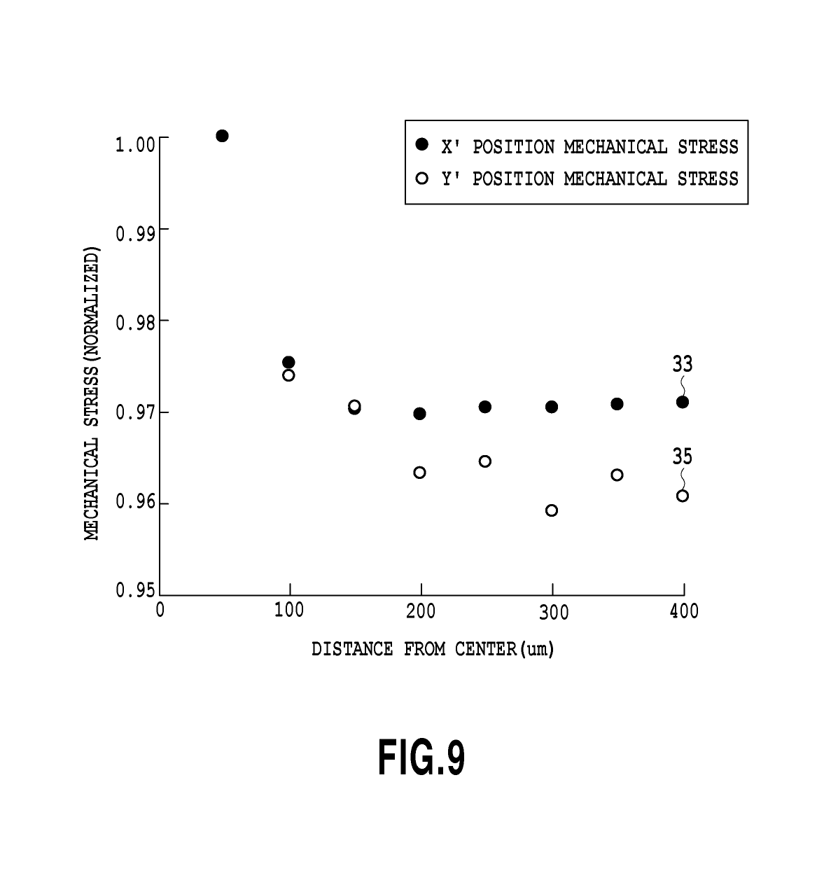

FIG. 9 is a diagram showing the relations between the measurement position and the mechanical stress. Filled-in circles 33 are indicative of the X′ axis direction, and blank circles 35 are indicative of the Y′ axis direction. FIG. 9 shows that, in the X′ axis direction, the mechanical stress increases with decreasing distance to the center and decreases with increasing distance from the center but remains constant when the distance from the center is about 200 μm or longer. In the Y′ axis direction, the mechanical stress similarly increases with decreasing distance to the center and decreases with increasing distance from the center. However, the mechanical stress starts to be constant when the distance from the center is about 300 μm.

### Embodiment 2

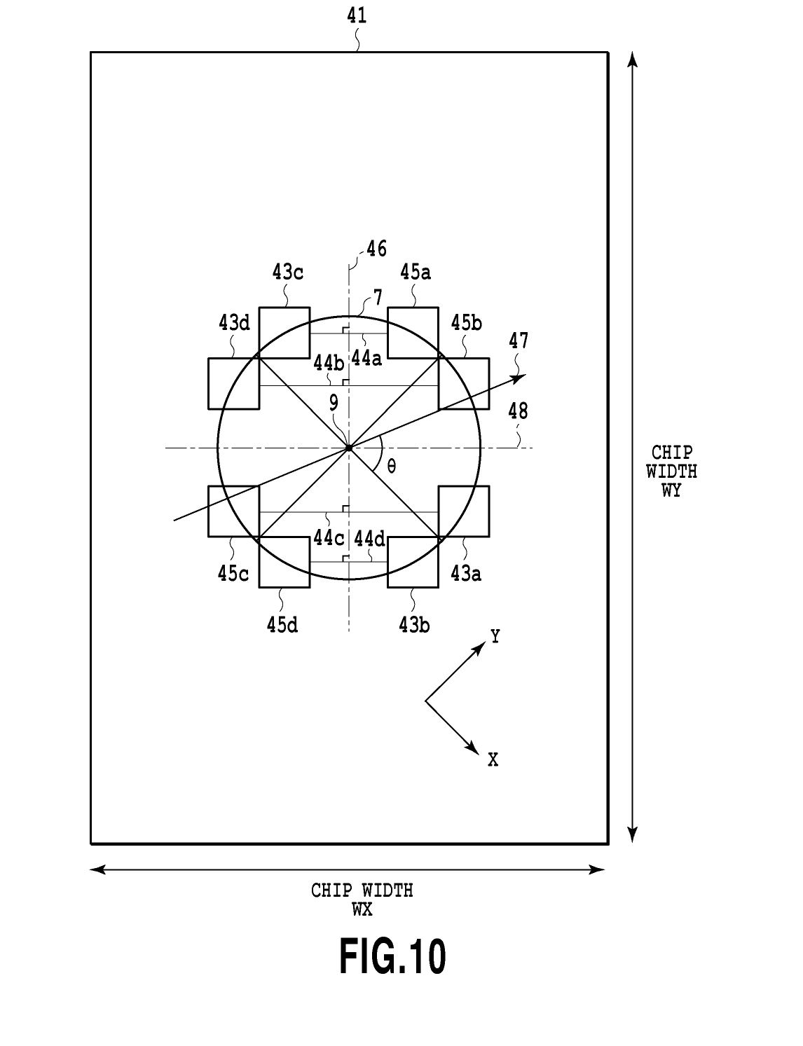

FIG. 10 is a diagram illustrating a rotation angle measuring chip 41 according to Embodiment 2 of the present invention. The rotation angle measuring chip 41 according to Embodiment % is different from the rotation angle measuring chip 1 according to Embodiment 1 in that the rotation angle measuring chip 41 includes four X axis Hall elements 43a to 43d and four Y axis Hall elements 45a to 45d. The Hall elements according to Embodiment 2 are arranged such that two sets each of two X axis Hall elements 43 (43a and 43b) and (43c and 43d) and two sets each of two Y axis Hall elements 45 (45a and 45b) and (45c and 45d) are installed at the respective positions where the Hall elements 11a, 11b, 13a, and 13b according to the Embodiment 1 are provided.

That is, the X axis Hall element 43c and the Y axis Hall element 45a are positioned at an equal distance from an axis of symmetry 46 which is parallel to a longitudinal direction of the rotation angle measuring chip 41 and which passes through a circle center point 9. A line segment 44a joining the two Hall elements 43c and 45a is orthogonal to the axis of symmetry 46. As in the case of the X axis Hall element 43c and the Y axis Hall element 45a positioned line-symmetrically with respect to the axis of symmetry 46, the two Hall elements in each combination of the X axis Hall element and the Y axis Hall element, that is, the Hall elements 43d and 45b, the Hall elements 43a and 45c, and the Hall elements 43b and 45d, are at an equal distance from the axis of symmetry 46. In addition, line segments 44b, 44c, and 44d each joining the two Hall elements are orthogonal to the axis of symmetry 46 and are thus positioned line-symmetrically with respect to the axis of symmetry 46.

Moreover, the X axis Hall elements 43b and 43c are positioned at an equal distance from the circle center point 9. A line segment joining the two Hall elements 43b and 43c together passes through the circle center point 9. As in the case of the X axis Hall elements 43b and 43c positioned point-symmetrically with respect to the circle center point 9, the two Hall elements in each combination of the X or Y axis Hall elements, that is, the X axis Hall elements 43a and 43d, the Y axis Hall elements 45a and 45d, and the Y axis Hall elements 45b and 45c, are positioned point-symmetrically with respect to the circle center point 9. Consequently, the rotation angle measuring chip 41 can detect more output signals and thus detect the rotation angle more accurately than the rotation angle measuring chip 1 according to Embodiment 1.

A method for detecting the rotation angle will be described with reference to FIG. 10. When a magnetic field 47 is applied as shown in FIG. 10, the X axis Hall elements (43a and 43b) and (43c and 43d) provide output differential voltages V(X1+), V(X2+), V(X1−), and V(X2−), respectively. The Y axis Hall elements (45a and 45b) and (45c and 45d) provide output differential voltages V(Y1+), V(Y2+), V(Y1−), and V(Y2−), respectively. These output differential voltages are such sine wave voltages and cosine wave voltages as expressed by Expression (7). Here, the X axis Hall element 43 and the Y axis Hall element 45 are located at an angle α to the X axis and the Y axis, respectively.

V(X1+)+V(X2+)=A1×cos(θ−α)+A1×cos(θ+α)

V(X1−)+V(X2−)=−A2×cos(θ+α)−A2×cos(θ−α)

V(Y1+)+V(Y2+)=A3×sin(θ−α)+A3×sin(θ+α)

V(Y1−)+V(Y2−)=−A4×sin(θ+α)−A4×sin(θ−α) (7)

Here, proportional constants A1, A2, A3, and A4 are used, and a counterclockwise angle (magnetic-field application angle) θ is subtended between the X axis direction and the direction of the magnetic field 47 in FIG. 10.

In this case, the Hall elements (43c and 43d) and (45a and 45b) are positioned line-symmetrically with respect to the axis of symmetry 46, and thus, substantially the same mechanical stress is applied to the Hall elements (43c and 43d) and (45a and 45b). Hence, A2=A3. Similarly, the Hall elements (45c and 45d) and (43a and 43b) are positioned line-symmetrically with respect to the axis of symmetry 46, and thus, substantially the same mechanical stress is applied to the Hall elements (45c and 45d) and (43a and 43b). Hence, A1=A4. As a result, Expression 7 can be approximated to:

V(X1+)+V(X2+)=A1×cos(θ−α)+A1×cos(θ+α)

V(X1−)+V(X2−)=−A2×cos(θ+α)−A2×cos(θ−α)

V(Y1+)+V(Y2+)=A2×sin(θ−α)+A2×sin(θ+α)

V(Y1−)+V(Y2−)=−A1×sin(θ+α)−A1×sin(θ−α) (7)′

The differences between the output voltages are determined as expressed by Expression (5) to derive output voltages Vx and Vy in the X axis direction and the Y axis direction.

$$\begin{matrix}\begin{matrix}Vx = ( V ( X 1 + ) + V ( X 2 + ) ) - ( V ( X 1 - ) + V ( X 2 - 1 ) ) \\ = 2 \times A 1 \times cos θ cos α + 2 \times A 2 \times cos θ cos α \\ = 2 ( A 1 + A 2 ) cos θ cos α\end{matrix} \\ \begin{matrix}Vy = ( V ( Y 1 + ) + V ( Y 2 + ) ) - ( V ( Y 1 - ) + V ( Y 2 - ) ) \\ = 2 \times A 2 \times sin θ cos α + 2 \times A 1 \times sin θ cos α \\ = 2 ( A 1 + A 2 ) cos θ cos α\end{matrix} & ( 8 ) \\ Vx = 2 ( A 1 + A 2 ) cos θ cos α \\ Vy = 2 ( A 1 + A 2 ) sin θ cos α & ( 9 )\end{matrix}$$

Hence, the rotation angle θ can be calculated in accordance with:

tan θ=Vy/Vx

∴θ=arctan(Vx/Vy) (10)

When the Hall elements are disposed as in Embodiment 2, even if two or more sets of Hall elements are provided, the impact of the mechanical stress applied to each Hall element can be mitigated. The output voltage has an equal coefficient for the X and Y axis directions, enabling a reduction in angular errors. Thus, even if a plurality of X axis Hall elements and a plurality of Y axis Hall elements are disposed, the rotation angle can be accurately measured.

The Hall elements may be disposed symmetrically with respect to an axis of symmetry 48 which passes through the circle center point 9 and which is parallel to the transverse direction of the rotation angle measuring chip 41. Furthermore, the magnetic field sensors may be vertical Hall elements, magnetoresistive elements, or the like.

### Embodiment 3

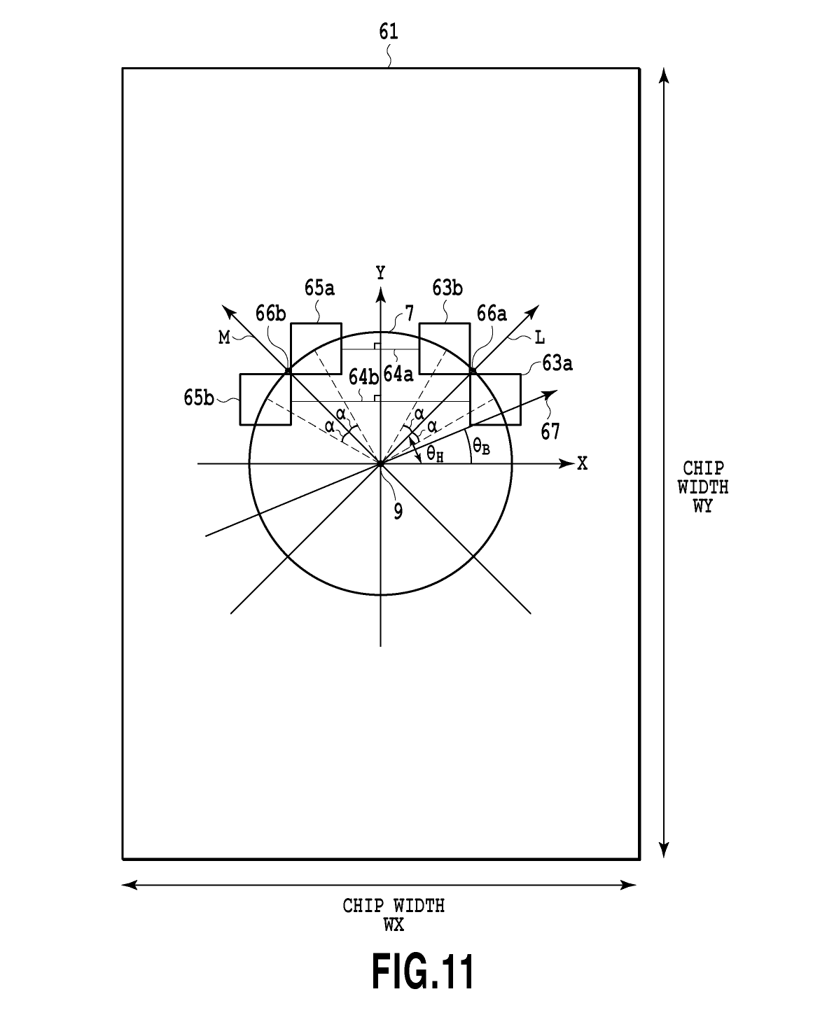

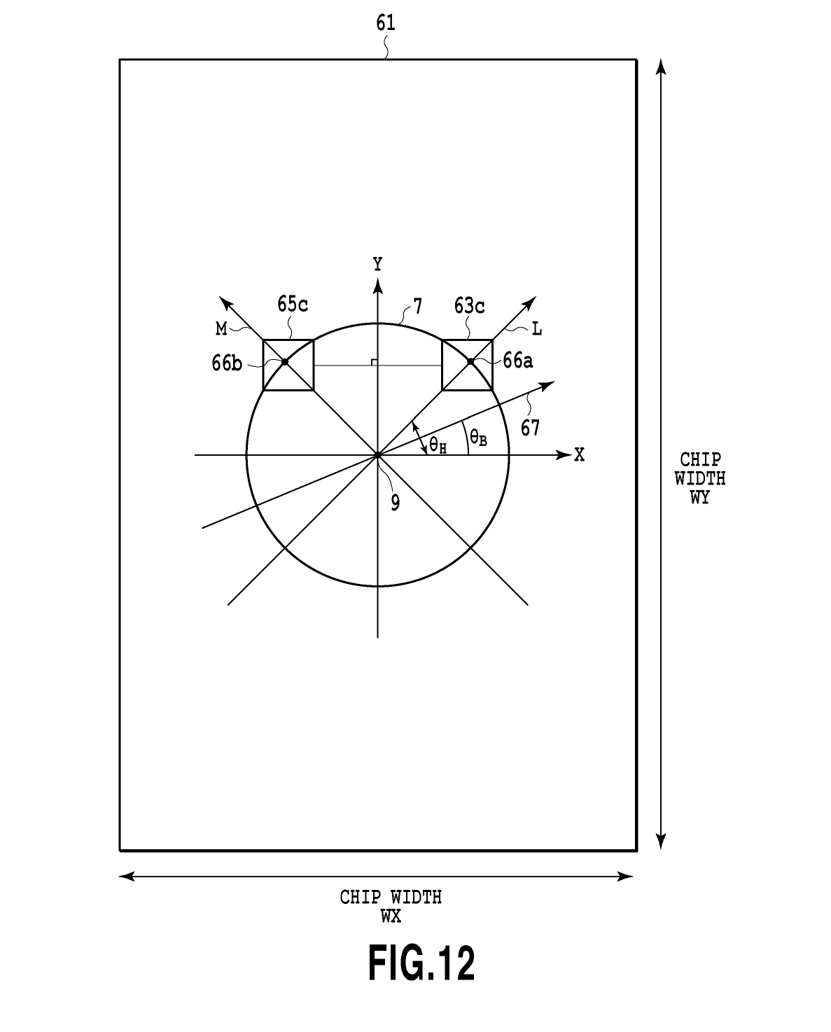

FIG. 11 and FIG. 12 are diagrams illustrating a rotation angle measuring chip 61 according to Embodiment 3 of the present invention. The rotation angle measuring chip 61 according to Embodiment 3 is different from the rotation angle measuring chip 1 and 41 according to Embodiments land 2 in that the rotation angle measuring chip 61 includes two sets each of two adjacent Hall elements (63a and 63b) and (65a and 65b) and that the rotation angle between the two sets around a circle center point 9 is different from the right angle. The rotation angle measuring chip 61 according to Embodiment 3 is also different from the rotation angle measuring chip 1 and 41 in that the Hall elements are not distinguished from one another depending on whether the Hall element is used for the X axis or for the Y axis. According to Embodiment 3, the X axis direction and Y axis direction in which the output voltage is derived are defined to be the transverse direction and longitudinal direction, respectively, of the rotation angle measuring chip 61. The two sets of Hall elements (63a and 63b) and (65a and 65b) are installed line-symmetrically with respect to the Y axis, passing through the circle center point 9 and serving as an axis of symmetry.

That is, the Hall elements 63a and 65b are positioned at an equal distance from the Y axis, serving as an axis of symmetry. The Hall elements 63b and 65a are also positioned at an equal distance from the Y axis. Line segments 64a and 64b joining the Hall elements 63a and 65b together and the Hall elements 63b and 65a, respectively, are each orthogonal to the Y axis. Furthermore, a straight line passing through the circle center point 9 and a tangent point 66a between the Hall elements 63a and 63b is referred to as a straight line L. A straight line passing through the circle center point 9 and a tangent point 66b between the Hall elements 65a and 65b is referred to as a straight line L.

A method for detecting the rotation angle will be described with reference to FIG. 11 and FIG. 12. When a magnetic field 67 is applied as shown in FIG. 11, output signals from the Hall elements 63a, 63b, 65a, and 65b are detected to derive output voltages Vx and Vy in the X axis direction and Y axis direction. Here, for simplification of calculations, the Hall elements (63a and 63b) and (65a and 65b) are replaced with Hall elements 63c and 65c located on a straight line L and a straight line M and centered around tangent points 66a and 66b, respectively; the tangent point 66a lies between the Hall elements 63a and 63b, and the tangent point 66b lies between the Hall elements 65a and 65b. In this case, the Hall elements 63c and 65c are positioned line-symmetrically with respect to the Y axis, serving as an axis of symmetry, as described above.

Proportional constants A1, A2, A3, and A4 are intended for the intensities of output signals from the Hall elements 63a, 63b, 65a, and 65b, respectively. The Hall elements 63a and 63b and the Hall elements 65a and 65b are located at an angle α to the straight line L and the straight line M, respectively. In this case, when proportional constants A12 and A34 are intended for the intensities of output signals from the Hall elements 63c and 65c, the following expression holds true.

A12═A1×cos α+A2×cos α=(A1+A2)cos α

A34=A3×cos α+A4×cos α=(A3+A4)cos α

Thus, the Hall elements (63a and 63b) and (65a and 65b) can be replaced with the Hall elements 63c and 65c, respectively.

The following definitions are applicable. The Hall elements 63c and 65c provide output differential voltages V(63c) and V(65c), respectively. Furthermore, a counterclockwise angle θ_{H} is subtended between the X axis direction and the direction of the straight line L. A counterclockwise angle (magnetic-field application angle) θ_{B} is subtended between the X axis direction and the direction of the magnetic field 67. These output differential voltages are such sine wave voltages and cosine wave voltages as expressed by:

V(63c)=A12×cos(θ_{H}−θ_{B})

V(65c)=−A34×cos(θ_{H}−θ_{H}) (11)

The following calculations are carried out to derive output voltages Vx and Vy in the X axis direction and the Y axis direction, thus determining a rotation angle θ_{B}.

$$\begin{matrix}Vx = V ( 63 c ) cos {θ}_{H} + V ( 65 c ) cos {θ}_{H} \\ = A 12 \times cos ( {θ}_{H} - {θ}_{B} ) cos {θ}_{H} + A 34 \times cos ( {θ}_{H} + {θ}_{B} ) cos {θ}_{H} \\ = cos {θ}_{H} \{ \begin{matrix}A 12 ( cos {θ}_{H} cos {θ}_{B} + sin {θ}_{H} sin {θ}_{B} ) + \\ A 34 ( cos {θ}_{H} cos {θ}_{B} - sin {θ}_{H} sin {θ}_{B} )\end{matrix} \}\end{matrix} \\ \begin{matrix}Vy = V ( 63 c ) sin {θ}_{H} + V ( 65 c ) sin {θ}_{H} \\ = A 12 \times cos ( {θ}_{H} - {θ}_{B} ) cos {θ}_{H} + A 34 \times cos ( {θ}_{H} + {θ}_{B} ) sin {θ}_{H} \\ = sin {θ}_{H} \{ \begin{matrix}A 12 ( cos {θ}_{H} cos {θ}_{B} + sin {θ}_{H} sin {θ}_{B} ) + \\ A 34 ( cos {θ}_{H} cos {θ}_{B} - sin {θ}_{H} sin {θ}_{B} )\end{matrix} \}\end{matrix} \qquad ( 12 )$$

In this case, the Hall elements 63c and 65c are positioned line-symmetrically with respect to the Y axis, and thus, substantially the same mechanical stress is applied to the Hall elements 63c and 65c. Hence, A12=A34=A. As a result, Expression (12) can be approximated to:

Vx=2A×cos²θ_{H} cos θ_{E},

Vy=2A×sin²θ_{H} sin θ_{B} (13).

Hence, the rotation angle θ_{B} can be calculated in accordance with:

$$\begin{matrix}Vx / Vy = {sin}^{2} {θ}_{H} sin {θ}_{B} / {cos}^{2} {θ}_{H} cos {θ}_{B} \\ = γ ( {θ}_{H} ) \times tan {θ}_{B}\end{matrix} \\ ∴ {θ}_{B} = arc tan ( Vy / γ ( {θ}_{H} ) Vx ) , \qquad ( 14 )$$

where γ(θ_{H}) is determined from any set value θ_{B} and known.

When the Hall elements are disposed as described in Embodiment 3, even if the rotation angle between the two sets of Hall elements around the circle center point 9 is different from the right angle, the impact of the mechanical stress applied to each Hall element can be mitigated. Thus, the coefficients of the output voltages in the X axis direction and the Y axis direction can be made equal. This enables a reduction in angular errors, allowing the rotation angle to be accurately detected.

### Embodiment 4

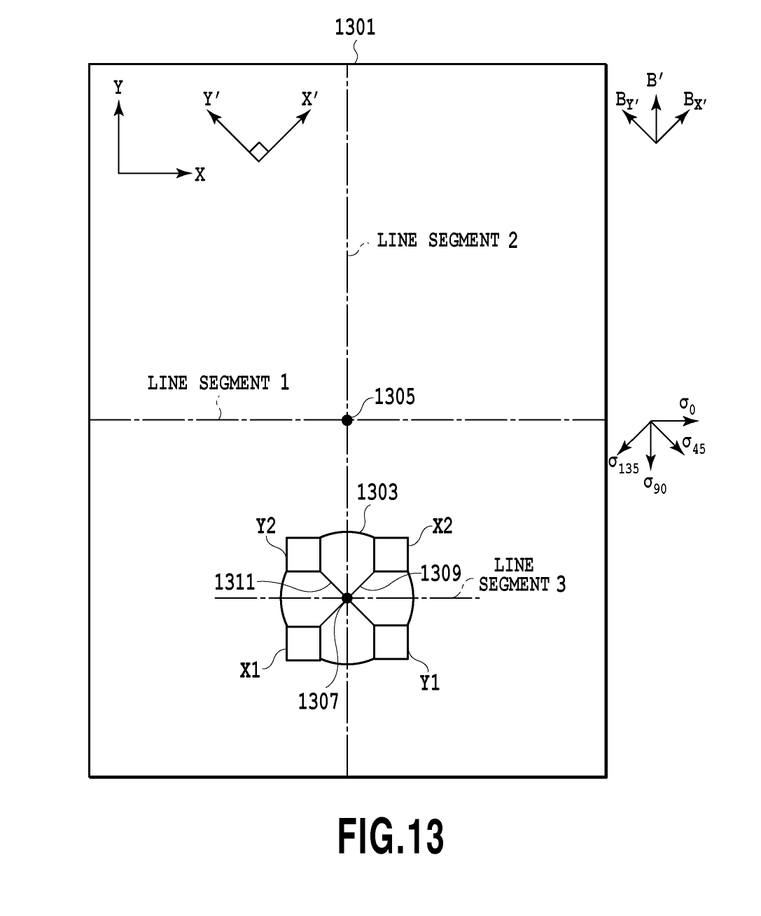

FIG. 13 is a configuration diagram illustrating a rotation angle measuring chip 1301 according to Embodiment 4 of the present invention. FIG. 13 also illustrates the positional relations between a magnetic flux concentrator 1303 and both Hall elements X and Y on the rotation angle measuring chip 1301. In FIG. 13, a line segment 1 is defined to pass through the midpoints of long sides of the rectangular rotation angle measuring chip 1301 and to be parallel to short sides of the rotation angle measuring chip 1301. A line segment 2 is defined to pass through the midpoints of the short sides of the rectangular rotation angle measuring chip 1301 and to be parallel to the long sides of the rotation angle measuring chip 1301. The line segment 1 and the line segment 2 cross at right angles at a center point 1305 of the rotation angle measuring chip 1301. Furthermore, a line segment 3 is defined to pass through a circle center point 1307 of a disc-like magnetic flux concentrator 1303 on the rotation angle measuring chip 1301 and to be parallel to the line segment 1.

The rotation angle measuring chip 1301 according to Embodiment 4 is different from the rotation angle measuring chips 1, 41, and 61 according to Embodiment 1 to Embodiment 3 in that the circle center point 1307 of the magnetic flux concentrator 1303 is on the line segment 2 but is not on the line segment 1. That is, Embodiment 4 illustrates that the center point 1305 of the rotation angle measuring chip 1301 does not coincide with the circle center point 1307 of the magnetic flux concentrator 1303.

On the circumference of the magnetic flux ux concentrator 1303, four Hall elements X1, X2, Y1, and Y2 are disposed at an equal distance from the circle center point 1307, as is the case with Embodiment 1. The Hall elements X1 and Y1 are disposed line-symmetrically with respect to the line segment 2. The Hall elements X2 and Y2 are disposed line-symmetrically with respect to the line segment 2. The Hall elements X1 and Y2 are disposed line-symmetrically with respect to the line segment 3. The Hall elements X2 and Y1 are disposed line-symmetrically with respect to the line segment 3.

Furthermore, a silicon substrate forming the rotation angle measuring chip 1301 and a package material (a mold resin or the like) have different liner expansion coefficients, and thus mechanical stress is generated at many points on a surface of the rotation angle measuring chip 1301. The direction of a mechanical stress at each point is defined by arrows (σ₀, σ₄₅, σ₉₀, and σ₁₃₅) in FIG. 13. A mechanical stress σ₀ is parallel to the short sides of the rotation angle measuring chip 1301. A mechanical stress σ₉₀ is parallel to the long sides of the rotation angle measuring chip 1301. Mechanical stresses σ₄₅ and σ₁₃₅ are at an angle of 45° to the short sides and long sides of the rotation angle measuring chip 1301. Furthermore, the X axis and the Y axis are defined to be directions parallel to the short sides and long sides, respectively, of the rotation angle measuring chip 1301. Moreover, when the X axis is a direction of 0°, an X′ axis is defined to be a direction of 45° counterclockwise, and a Y′ axis is defined to be a direction of 135° counterclockwise. A counterclockwise angle between the X′ axis direction and the Y′ axis direction is defined to be θ. The X′ axis is parallel to a line segment 1309 joining the Hall elements X1 and X2 together. The V axis is parallel to a line segment 1311 joining the Hall elements Y1 and Y2 together. The line segment 1309 and the line segment 1311 cross at right angles at the circle center point 1307.

Here, when a magnetic field B is present in a direction parallel to the rotation angle measuring chip 1301, a magnetic-field component B_{X′, is parallel to the X′ axis, and a magnetic-field component B}_{Y′}, is parallel to the Y′ axis. A counterclockwise angle θ_{B} is subtended between the X′ direction and the direction of the magnetic field B. That is, the angle between the X axis and the Y axis is 90°, and the angle between the X′ axis and the Y′ axis is also 90°.

The output voltages V(X1), V(X2), V(Y1), and V(Y2) from the respective Hall elements X1, X2, Y1, and Y2 are expressed by Expression (15) shown below. Here, a current i flows through the magnetic flux concentrator 1303. The Hall elements X1, X2, Y1, and Y2 have magnetic sensitivities SIₓ₁, SI_{X2}, SY_{Y1}, and SI_{Y2} and offsets Offset_{X1}, Offset_{X2}, Offset_{Y1}, and Offset_{Y2}, respectively. To allow the direction of the magnetic field B, which is horizontal with respect to the surface of the rotation angle measuring chip 1301, to be accurately calculated using Expression (15), the offsets Offset_{X1} and Offset_{Y2} need to be sufficiently small compared to the offset of a signal proportional to the magnetic field B and the sum of magnetic sensitivities of the Hall elements X1 and X2 needs to be equal to the sum of magnetic sensitivities of the Hall elements Y1 and Y2, as expressed by Expression (16).

$$\begin{matrix} V ( X 1 ) = - {SI}_{X 1} \times I \times {B}_{{x}^{′}} + {Offset}_{X 1} \\ V ( X 2 ) = {SI}_{X2} \times I \times {B}_{{x}^{′}} + {Offset}_{X 2} \\ V ( Y 1 ) = - {SI}_{Y 1} \times I \times {B}_{{y}^{′}} + {Offset}_{Y 1} \\ V ( Y 2 ) = {SI}_{Y 2} \times I \times {B}_{{y}^{′}} + {Offset}_{Y 2} & ( 15 ) \\ {θ}_{B} = arc tan ( \frac{V ( Y 2 ) - V ( Y 1 )}{V ( X 2 ) - V ( X 1 )} ) \\ \frac{V ( Y 2 ) - V ( Y 1 )}{V ( X 2 ) - V ( X 1 )} = \frac{( {SI}_{Y 2} + {SI}_{Y 1} ) \times I \times {B}_{{y}^{′}} + ( {Offset}_{Y 2} - {Offset}_{Y 1} )}{( {SI}_{X 2} + {SI}_{X 1} ) \times I \times {B}_{{x}^{′}} + ( {Offset}_{X 2} - {Offset}_{X 1} )} \\ If ( {Offset}_{Y 2} - {Offset}_{Y 1} ) ≅ 0 \& ( {Offset}_{X 2} - {Offset}_{X 1} ) ≅ 0 \\ Then \\ \frac{V ( Y 2 ) - V ( Y 1 )}{V ( X 2 ) - V ( X 1 )} ≅ \frac{( {SI}_{Y 2} + {SI}_{Y 1} ) \times {B}_{{y}^{′}}}{( {SI}_{X 2} + {SI}_{X 1} ) \times {B}_{{x}^{′}}} \\ If ( {SI}_{X 2} + {SI}_{X 1} ) ≅ ( {SI}_{Y 2} + {SI}_{Y 1} ) \\ Then \\ \frac{V ( Y 2 ) - V ( Y 1 )}{V ( X 2 ) - V ( X 1 )} ≅ \frac{{B}_{{y}^{′}}}{{B}_{{x}^{′}}} \\ ⇒ {θ}_{B} = arc tan ( \frac{{B}_{{y}^{′}}}{{B}_{{x}^{′}}} ) & ( 16 )\end{matrix}$$

The magnetic sensitivities SI_{X1} and SI_{Y2} of the Hall elements are affected by mechanical stress. This effect is referred to as a piezo-Hall effect and expressed by Expression (17) using a piezo-Hall coefficient P₁₂.

The state in which “the sum of magnetic sensitivities of the Hall elements X1 and X2 is equal to the sum of magnetic sensitivities of the Hall elements Y1 and Y2” can be accurately established when the following conditions are met: (i) the magnetic sensitivity obtained without mechanical stress is substantially equal among all the Hall elements, (ii) the mechanical stresses of the Hall elements X1 and Y1 are substantially equal, and (iii) the mechanical stresses of the Hall elements X2 and Y2 are substantially equal. The condition (i) can be met by producing all the Hall elements X1, X2, Y1, and Y2 under the same conditions so that the elements have the same shape. The condition (ii) can be met by disposing the Hall elements X1 and Y1 line-symmetrically with respect to a line segment 2 which passes through the center point of the silicon substrate and which is parallel to the long sides of the substrate. This is because when the Hall elements are symmetrically shaped, possible mechanical stresses are also symmetric. The condition (iii) can also be met by disposing the Hall elements X2 and Y2 line-symmetrically with respect to the line segment.

SI_{X1}=SI_{X10}(1+P₁₂(σ₄₅+σ₁₃₅)_{X1})

SI_{X2}=SI_{X20}(1+P₁₂(σ₄₅+σ₁₃₅)_{X2})

SI_{Y1}==SI_{Y10}(1+P₁₂(σ₄₅+σ₁₃₅)_{Y1})

SI_{Y2}=SI_{X20}(1+P₁₂(σ₄₅+σ₁₃₅)_{Y2}) (17)

SIoo0: magnetic sensitivity obtained during a mechanical stress free period

(σ₄₅+σ₁₃₅)oo:(σ₄₅+σ₁₃₅) applied to the position of the Hall element oo.

The Hall elements disposed line-symmetrically with respect to the line segment 1 or the line segment 2 are subjected to an almost equal mechanical stress. The piezo-Hall effect does not depend on the number of Hall elements. Thus, given a group of Hall elements with line-symmetrically positioned sets each of two Hall elements, the piezo-Hall effect works on at least one set of Hall elements positioned line-symmetrically with respect to the line segment 1 or the line segment 2. Furthermore, this effect also works on a magnetic-field measuring apparatus requiring no magnetic flux concentrator.

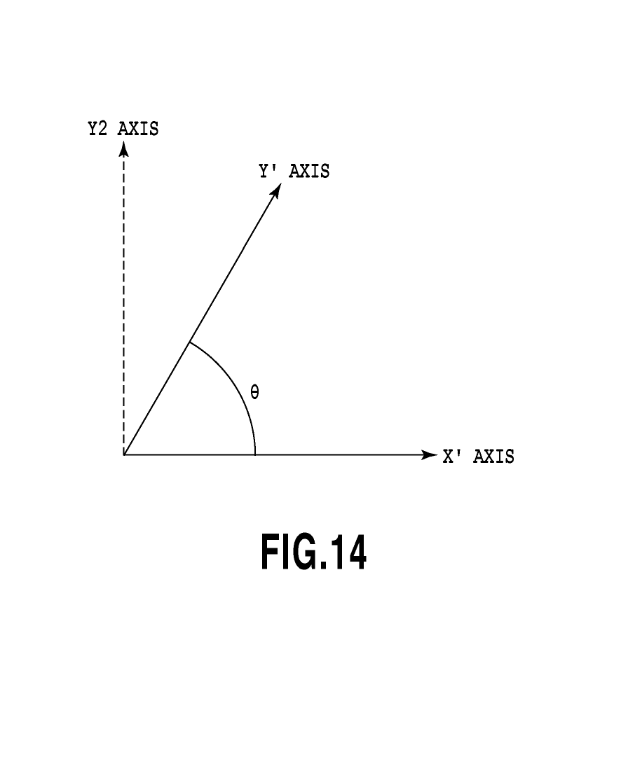

FIG. 14 is a diagram showing that the angle between the X′ axis and the Y′ axis is not limited to 90° and is defined to be 0 degrees. In FIG. 13, the angle between the X′ axis and the Y′ axis is 90°. However, the angle need not be 90° and may have any known designed value. This is because even if the angle between the X′ axis and the Y′ axis is designed to be 0 degrees, the magnetic-field intensities in two Y axis directions perpendicular to the X′ axis can be easily calculated from the magnetic-field intensity in the Y′ axis direction.

The present embodiment illustrates that the center point 1307 is on the line segment 2. However, the present invention can be implemented even if the center point 1307 is on the line segment 1 and is not on the line segment 2.

### Embodiment 5

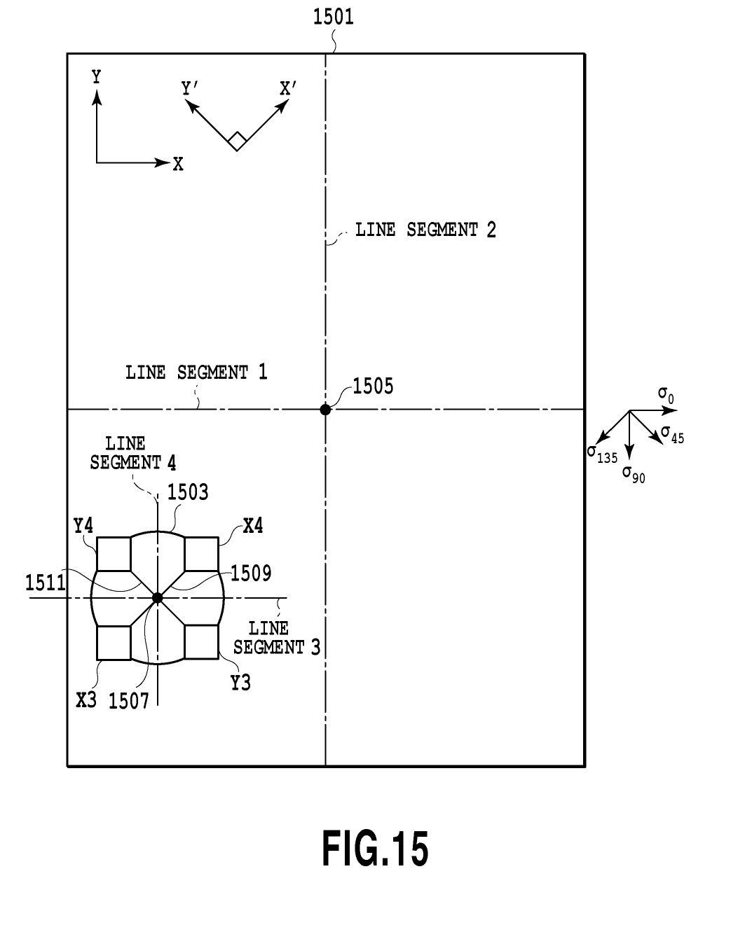

FIG. 15 is a configuration diagram illustrating a rotation angle measuring chip 1501 according to Embodiment 5 of the present invention. FIG. 15 also illustrates the positional relations between a magnetic flux concentrator 1503 and both Hall elements X and Y on the rotation angle measuring chip 1501. In FIG. 15, a line segment 1 and a line segment 2 are provided, and the line segment 1 and the line segment 2 are defined to cross at right angles at a center point 1505 of the rotation angle measuring chip 1501, like in the case of FIG. 13. Furthermore, a line segment 3 is defined to pass through a circle center point 1507 of a magnetic flux concentrator 1503 and to be parallel to the line segment 1. A line segment 4 is defined to pass through the circle center point 1507 and to be parallel to the line segment 2.

The rotation angle measuring chip 1501 according to Embodiment 1 is different from the rotation angle measuring chip 1301 according to Embodiment in that the circle center point 1507 of the magnetic flux concentrator 1503 is not on the line segment 1 or on the line segment 2. On the circumference of the magnetic flux concentrator 1503, four Hall elements X3, X4, Y3, and Y4 are disposed at an equal distance from the circle center point 1507, as is the case with Embodiment 4. The Hall elements X3 and Y3 are disposed line-symmetrically with respect to the line segment 4. The Hall elements X4 and Y4 are disposed line-symmetrically with respect to the line segment 4. The Hall elements X3 and Y4 are disposed line-symmetrically with respect to the line segment 3. The Hall elements X4 and Y3 are disposed line-symmetrically with respect to the line segment 3.

In the vicinity of the center point 1505 of the rotation angle measuring chip 1501, a mechanical stress exerted in a direction perpendicular to the rotation angle measuring chip 1501 is sufficiently lower than a mechanical stress exerted in a direction parallel to the rotation angle measuring chip 1501. Thus, the mechanical stress exerted in the direction perpendicular to the rotation angle measuring chip 1501 is almost negligible. On the other hand, in the vicinity of edge of the rotation angle measuring chip 1501, the amount of the mechanical stress exerted in the direction perpendicular to the rotation angle measuring chip 1501 is non-negligible compared to the amount of the mechanical stress exerted in the direction parallel to the rotation angle measuring chip 1501. The mechanical stress exerted in the direction perpendicular to the rotation angle measuring chip 1501 significantly affects the magnetic sensitivity and offset of each Hall element.

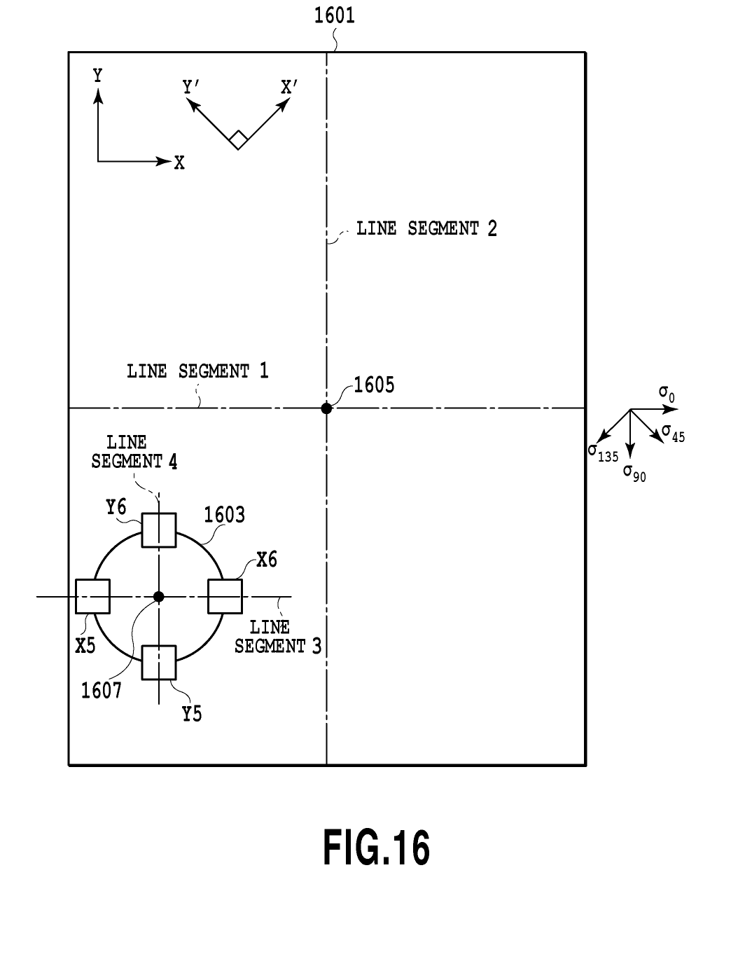

FIG. 16 is a diagram showing an arrangement of H elements compared to the arrangement of the Hall elements according to Embodiment 5 in FIG. 15. In FIG. 16, a magnetic flux concentrator 1603 is installed on a rotation angle measuring chip 1601, and four Hall elements X5, X6, Y5, and Y6 are disposed at an equal distance from a circle center point 1607, like in the case of FIG. 15. Furthermore, as is the case with FIG. 15, a line segment 1 and a line segment 2 are defined to cross at right angles at a center point 1605 of the rotation angle measuring chip 1601, a line segment 3 is defined to pass through a circle center point 1607 of a magnetic flux concentrator 1603 and to be parallel to the line segment 1, and a line segment 4 is defined to pass through the circle center point 1607 and to be parallel to the line segment 2. The Hall elements X5, X6, Y5, and Y6 correspond to the Hall elements X3, X4, Y3, and Y4.

The rotation angle measuring chip 1601 in FIG. 16 is different from the rotation angle measuring chip 1501 according to Embodiment 5 in that the Hall elements X5 and X6 are on the line segment 3 and that the Hall elements Y5 and Y6 are on the line segment 4.

In FIG. 16, only the Hall element X5, one of the four Hall elements, is close to an edge of the rotation angle measuring chip 1601 and is affected by the mechanical stress exerted in the direction perpendicular to the rotation angle measuring chip 1601. Thus, when X1 is substituted with X5 in the calculation of Expression (15), an error may occur when the angle θ_{B} of the magnetic field B is determined in accordance with Expression (16) because the magnetic sensitivity SI_{X5} and offset Offset_{X5} of the Hall element X5 are significantly different from the magnetic sensitivities and offsets of the other Hall elements.

On the other hand, when the Hall elements are disposed according to the present embodiment in FIG. 15, the Hall elements X3 and Y4 are close to an edge of the rotation angle measuring chip 1601. Thus, the magnetic sensitivities and offsets of the Hall elements X3 and Y4 are affected by the mechanical stress exerted in the direction perpendicular to the rotation angle measuring chip 1601, but in the calculation of a ratio (Y/X) or a difference (Y−X), the impacts of the magnetic sensitivities and offsets of the Hall elements X3 and Y4 offset each other, leading to the unlikelihood of an error when the angle θ_{B} of the magnetic field B is determined. Here, the present embodiment substitutes X1, X2, Y1, and Y2 in Expressions (15) and (16) with X3, X4, Y3, and Y4 for calculations.

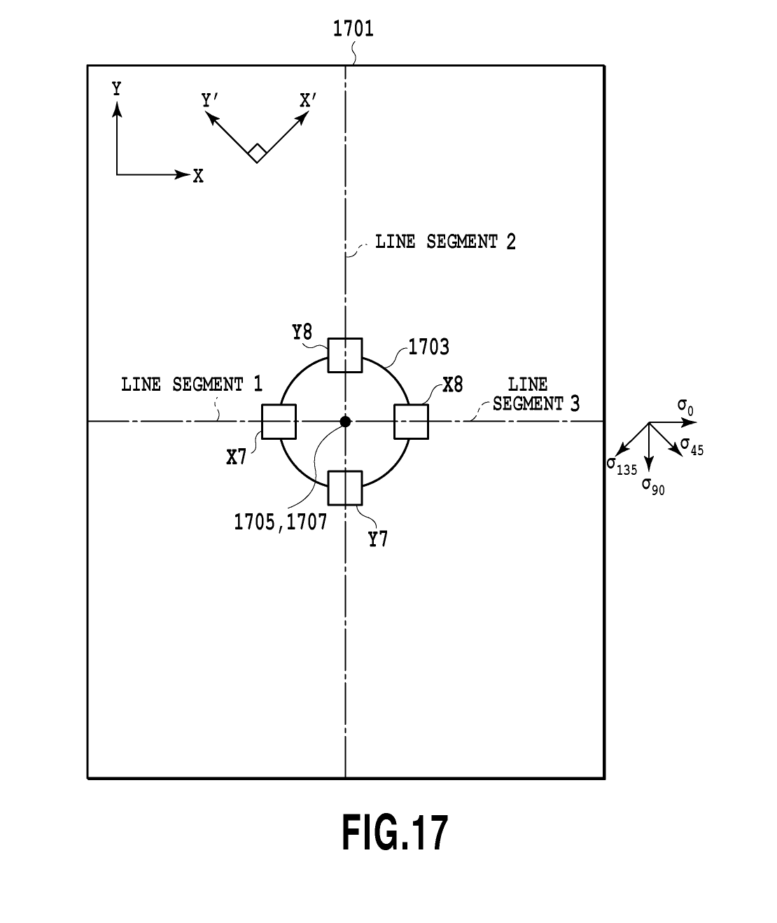

FIG. 17 is a diagram showing an arrangement of a magnetic flux concentrator 1703 and Hall elements on a conventional rotation angle measuring chip 1701. In FIG. 17, the magnetic flux concentrator 1703 is installed on the rotation angle measuring chip 1701, and four Hall elements X7, X8, Y7, and Y8 are disposed at an equal distance from a circle center point 1707. The rotation angle measuring chip 1701 in FIG. 17 is different from the rotation angle measuring chip 1601 in FIG. 16 in that a center point 1705 of the rotation angle measuring chip 1701 coincides with a circle center point of the magnetic flux concentrator 1703 and that the Hall elements X7 and X8 are on a line segment 1, while the Hall elements Y7 and YB are on a line segment 2.

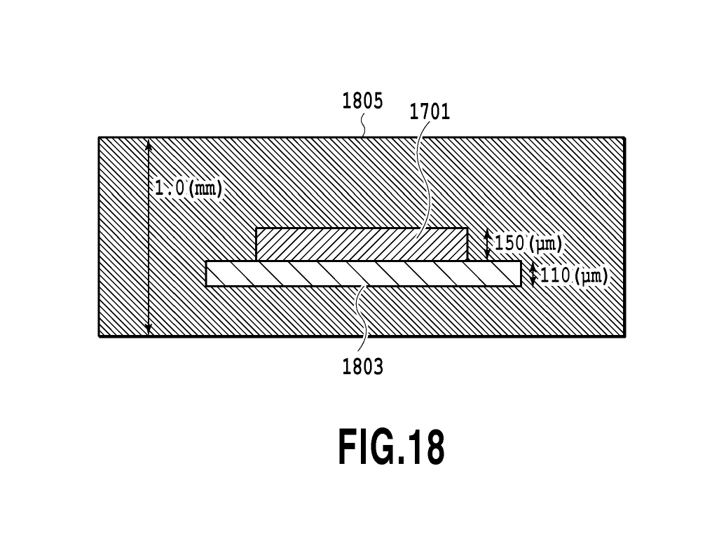

FIG. 18 is a cross-sectional view of a rotation angle measuring apparatus using the conventional rotation angle measuring chip 1701. A lead frame 1803 that is a rectangular chip mounted substrate on which the rotation angle measuring chip 1701 is installed is covered with a package external-form 1805. The rotation angle measuring chip 1701 is installed in a central portion of an upper surface of the lead frame 1803 so that each side of the rotation angle measuring chip 1701 is parallel to the corresponding side of the lead frame 1803.

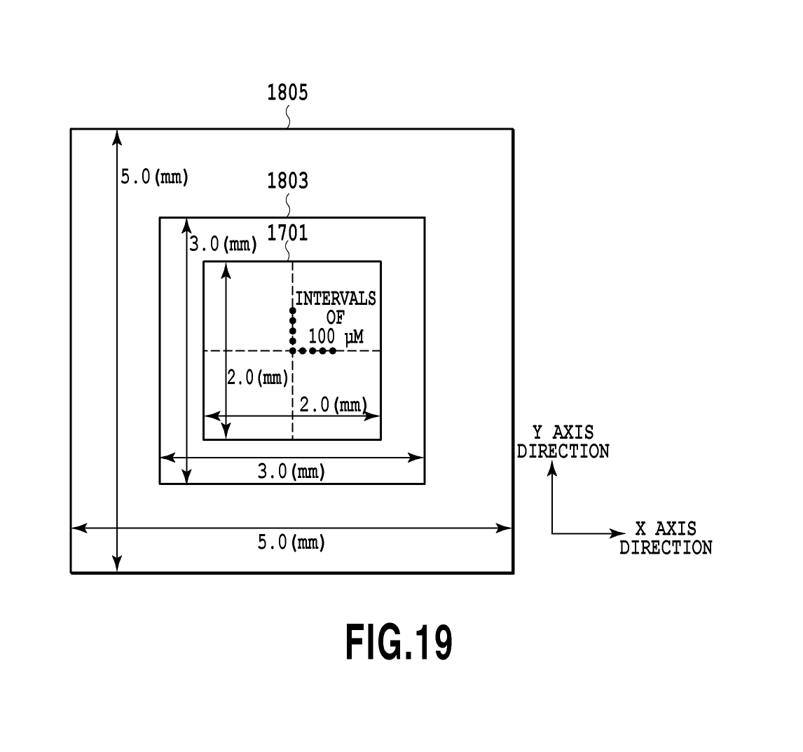

FIGS. 19 to 21 are diagrams illustrating a comparison of mechanical stresses exerted in the longitudinal direction of the conventional rotation angle measuring chip 1701 and in the transverse direction thereof. To clarify the effects of the present invention, mechanical stresses on the rotation angle measuring chip 1701 were simulated with the transverse length of the rotation angle measuring chip 1701 varied. By way of example, FIGS. 19 to 21 show that the lead frame 1803 is square.

FIG. 19 shows that the length of the rotation angle measuring chip 1701 is 2.0 mm in the longitudinal direction (X axis direction) and is 2.0 mm in the transverse direction (Y axis direction).

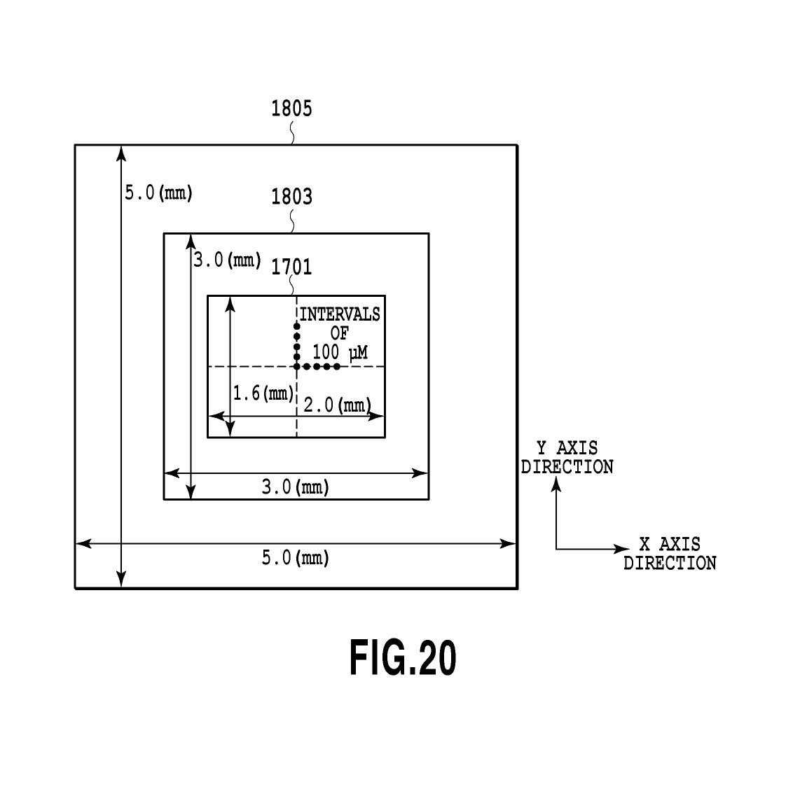

FIG. 20 shows that the length of the rotation angle measuring chip 1701 is 2.0 mm in the longitudinal direction (X axis direction) and is 1.6 mm in the transverse direction (Y axis direction).

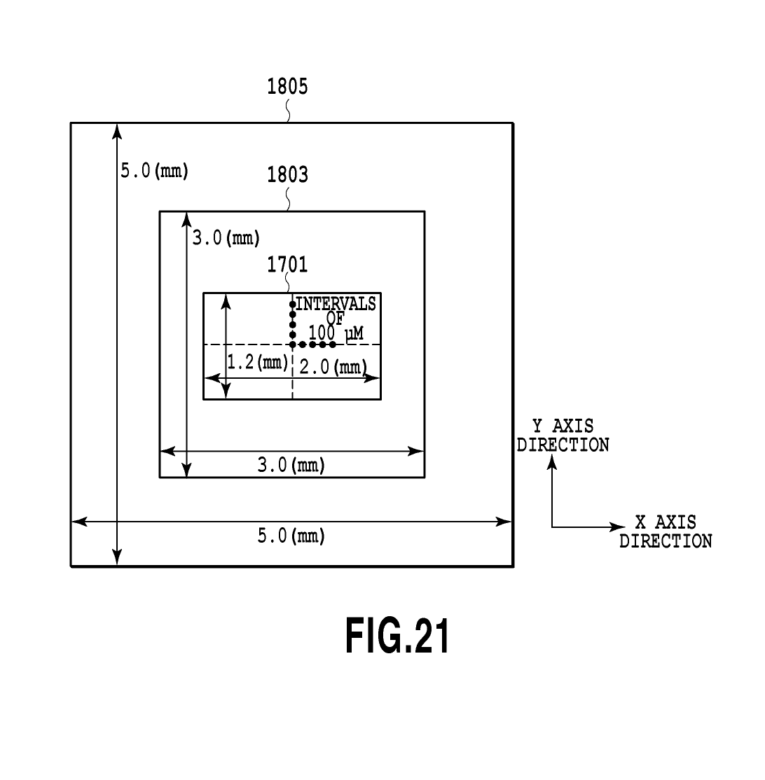

FIG. 21 shows that the length of the rotation angle measuring chip 1701 is 2.0 mm in the longitudinal direction (X axis direction) and is 1.2 mm in the transverse direction (Y axis direction).

Plots close to the center of the rotation angle measuring chip 1701 in FIGS. 19 to 21 correspond to points for which the mechanical stress is calculated. The mechanical stress is calculated at intervals of 100 μm in the X axis direction and in the Y axis direction starting from the center of rotation angle measuring chip 1701. A comparison of mechanical stresses exerted at the respective points on the X axis and the Y axis which are at an equal distance from the center of the rotation angle measuring chip 1701 enables a comparison between a mechanical stress applied to the X axis Hall elements X7 and X8 and a mechanical stress applied to the Y axis Hall elements Y7 and Y8.

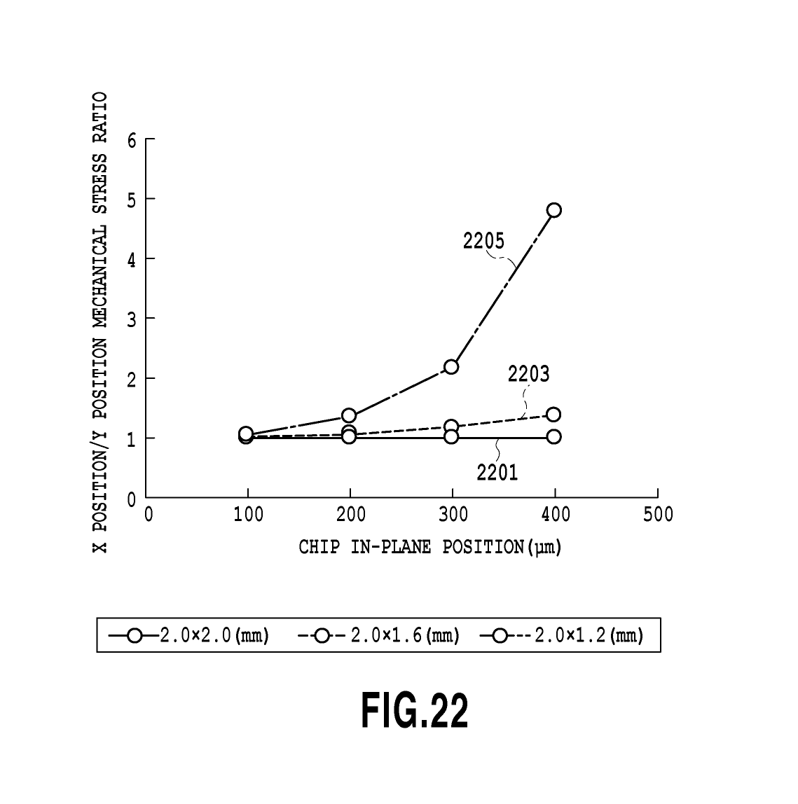

FIG. 22 is a diagram showing the ratio of mechanical stresses exerted at the respective points on the X axis and the Y axis which are at an equal distance from the center of the conventional rotation angle measuring chip 1701 in FIGS. 19 to 21. Line graphs 221, 2203, and 2205 in FIG. 22 show the results of calculation of the mechanical stress ratio (mechanical stress on the X axis/mechanical stress on the Y axis) of mechanical stresses exerted at the respective locations on the X axis and the axis which are at an equal distance from the center of the rotation angle measuring chip 1701 in FIG. 19, FIG. 20, and FIG. 21. The present embodiment calculates the mechanical stress ratio of the mechanical stress on the X axis/the mechanical stress on the Y axis. However, the mechanical stress ratio to be calculated may be the mechanical stress on the Y axis/the mechanical stress on the X axis.

The results shown in FIG. 22 indicate that the difference between the mechanical stress applied to the Y axis Hall element and the mechanical stress applied to the X axis Hall element increases consistently with the ratio between the short side and long side of the rotation angle measuring chip 1701. The arrangement of the Hall elements at the positions according to the present invention prevents an error in the angle of the magnetic field which is to be determined and which is caused by the difference in mechanical stress. That is, the effects of the present invention increase consistently with the ratio of the short side to long side of the rotation angle measuring chip.

According to the present invention, the ratio of the short side to long side (the length of the long side/the length of the short side) of the rotation angle measuring chip may be set to 1.3 or more, 1.5 or more, 1.8 or more, or 2.0 or more. That is, the present invention can be implemented regardless of the magnitude of value of the ratio of the short side to long side of the rotation angle measuring chip 1701.

According to the above-described embodiments, a magnetic-field application angle θ1 calculated by the rotation angle measuring apparatus (rotation angle sensor) is preferably converted into an angle based on the longitudinal direction or transverse direction of the rotation angle measuring chip. That is, when the longitudinal direction of the rotation angle measuring chip is defined to be the X axis direction and an angle θ2 is defined to be subtended between the X axis direction and the X′ axis direction, the rotation angle measuring apparatus (rotation angle sensor) calculates θ1+θ2 to obtain a magnetic-field application angle and converts the magnetic-field application angle into an angle based on the longitudinal direction of the rotation angle measuring chip.

A method for converting the magnetic-field application angle is not particularly limited, but preferably involves arithmetic processing (software conversion). Convenience for users is improved by making settings that allow the angle θ to be subjected to the arithmetic processing (software conversion) and converted into the angle θ1+θ2, that is, settings that allow the basis for the magnetic-field application angle to be converted into the longitudinal direction of the rotation angle measuring chip. The above-described embodiments define the longitudinal direction of the rotation angle measuring chip to be the X axis direction. However, the transverse direction may be defined to be the X axis direction.

The above-described embodiments illustrate the examples of four Hall elements. However, the embodiments can exert similar effects regardless of an increase in the number of Hall elements. That is, for example, if two line-symmetrically positioned Hall elements are considered to be one Hall element group, the embodiments are effective on at least one Hall element group positioned line-symmetrically with respect to the line segment 3 or line segment 4 perpendicular to one side of the rotation angle measuring chip 1501 where the Hall element is closest to the corresponding edge of the rotation angle measuring chip 1501.

According to the above-described embodiments, the magnetic flux concentrator is shaped like a circle. However, the Magnetic flux concentrator may be shaped like a polygon, an ellipse, or a sector. Furthermore, any distance may be set between the magnetic flux concentrator and the Hall element. The Hall element may be located immediately below the magnetic flux concentrator or the Hall element and the magnetic flux concentrator may appear to overlap when viewed in plane.

Furthermore, the above-described embodiments use the Hall elements as magnetic field sensors. However, vertical Hall elements, magnetoresistive elements, or the like may be used.

Embodiments 1 to 5 take the rotation angle measuring apparatus as an example. However, when the magnetic field in the rotator in the rotation angle measuring apparatus is replaced with geomagnetism, all the embodiments relate to an azimuth detector. Similarly, when the direction of a magnetic field induced by a current is measured, the direction of the magnetic field can be accurately measured, allowing the direction of the current to be measured.

Furthermore, the magnetic-field direction measuring apparatus and the rotation angle measuring chip according to the embodiments are very effective for detecting the direction of a magnetic field that is horizontal with respect to the chip.

Additionally, the magnetic-field direction measuring apparatus and the rotation angle measuring chip according to the embodiments is more significantly advantageous than the conventional technique when the substrate is shaped like a rectangle in which one side is longer than the other side.

### Embodiment 6

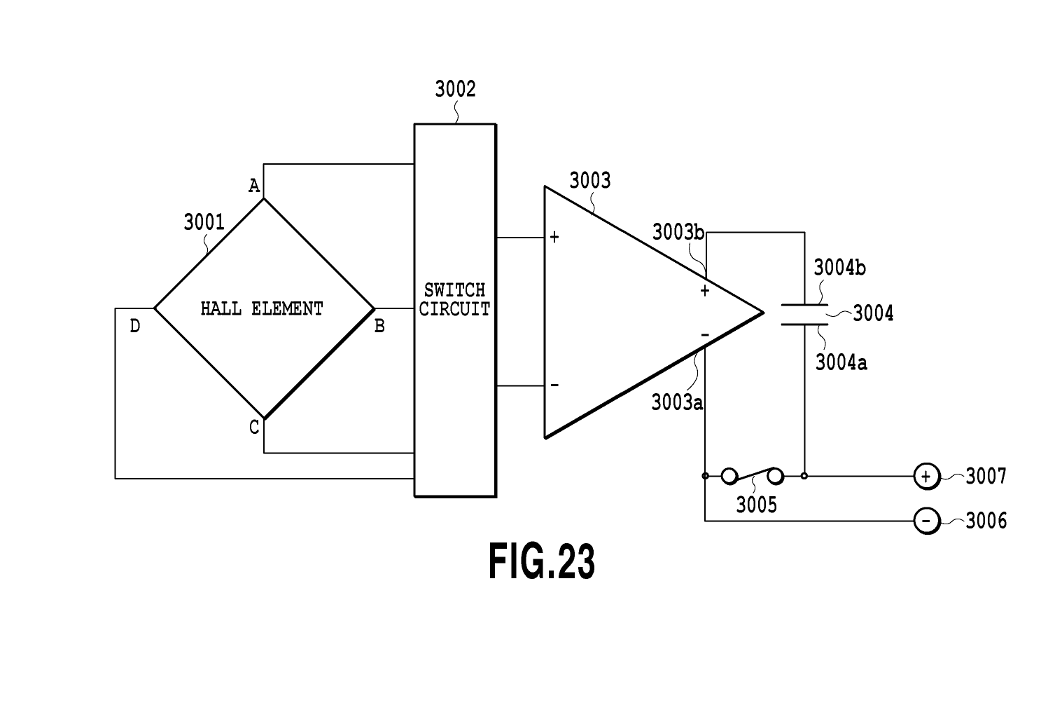

FIG. 23 is a circuit diagram showing a conventional magnetic sensor with the impact of offset voltages reduced. A Hall element used in the magnetic sensor is formed like a plate with a shape that is geometrically equivalent with respect to four terminals A, C, B, and D. Here, the geometrical y equivalent shape means that the shape of the Hall element remains the same after the four terminals A-C and B-D are rotated by 90° (the Hall element is rotated such that A-C coincides with B-D) as is the case with a quadrangular Hall element 3001. For a voltage generated between the terminals B and D of the Hall element 3001 when a power supply voltage is applied to between the terminals A and C of the Hall element 3001 and a voltage generated between the terminals A and C when the power supply voltage is applied to between the terminals B and D, effective signal components associated with the intensity of a magnetic field are in phase, and element offset voltages have reverse phases.

First, at a first timing, the power supply voltage is applied to between the terminals A and C of the Hall element 3001 via a switch circuit 3002, and the voltage between the terminals B and D is input to a voltage amplifier 3003. Thus, the voltage amplifier 3003 outputs a voltage V1 proportional to the sum of the voltage between the terminals B and D and an input offset voltage of the voltage amplifier 3003. Furthermore, at the first timing, a switch 3005 is closed to charge a capacitor 3004 to the voltage V1.

Then, at a second timing, the power supply voltage is applied to the terminals B and D of the Hall element 3001, and the voltage between the terminals C and A is input to the voltage amplifier 3003 to obtain a polarity opposite to the polarity obtained at the first timing. Thus, the voltage amplifier 3003 outputs a voltage V2 proportional to the sum of the voltage between the terminals C and A and the input offset voltage of the voltage amplifier 3003.

The impact of the input offset voltage is the same as the impact made at the first timing regardless of the polarity of the input voltage. Thus, the output voltage V2 of the voltage amplifier 3003 is proportional to the sum of the input offset voltage and the voltage between the terminals C and A, having a polarity reverse to the polarity obtained at the first timing.

Furthermore, at the second timing, the switch 3005 is opened to connect an inverting output terminal 3003a and a non-inverting output terminal 3003b of the voltage amplifier 3003 in series with a capacitor 3004. At this time, the voltage charged in the capacitor 3004 is held unchanged at the output voltage V1 of the voltage amplifier 3003 obtained at the first timing. A voltage (an output voltage from the magnetic-field sensor) V between the output terminals 3006 and 3007 is the sum of the voltage V2 of the non-inverting output terminal 3003b of the voltage amplifier 3003 based on the inverting output terminal 3003a of the voltage amplifier 3003 and a voltage −V1 of a terminal 3004a of the capacitor 3004 based on a terminal 3004b of the capacitor 3004, that is, the voltage V is the voltage V2 minus the voltage V1. Thus, the resultant output voltage from the magnetic-field sensor is the voltage V with the impact of the input offset voltage cancelled.

The conventional technique disadvantageously involves a high offset voltage generated in response to mechanical stress applied to the Hall element by the magnetic flux concentrator. Furthermore, the Hall element fail to be disposed so as to reduce the impact, on the offset voltage, of the mechanical stress applied by the magnetic flux concentrator, resulting in a significant offset.

A magnetic-field measuring apparatus will be described below which takes the positional relations between the Hall element and the substrate and the magnetic flux concentrator into account to reduce the offset voltages.

A magnetic-field measuring apparatus according to the present invention will be described below with reference to the drawings. In the magnetic-field measuring apparatus according to the present invention, the longitudinal direction of an Si substrate is defined to be the X axis direction. The transverse direction of the Si substrate is defined to be the Y axis direction.

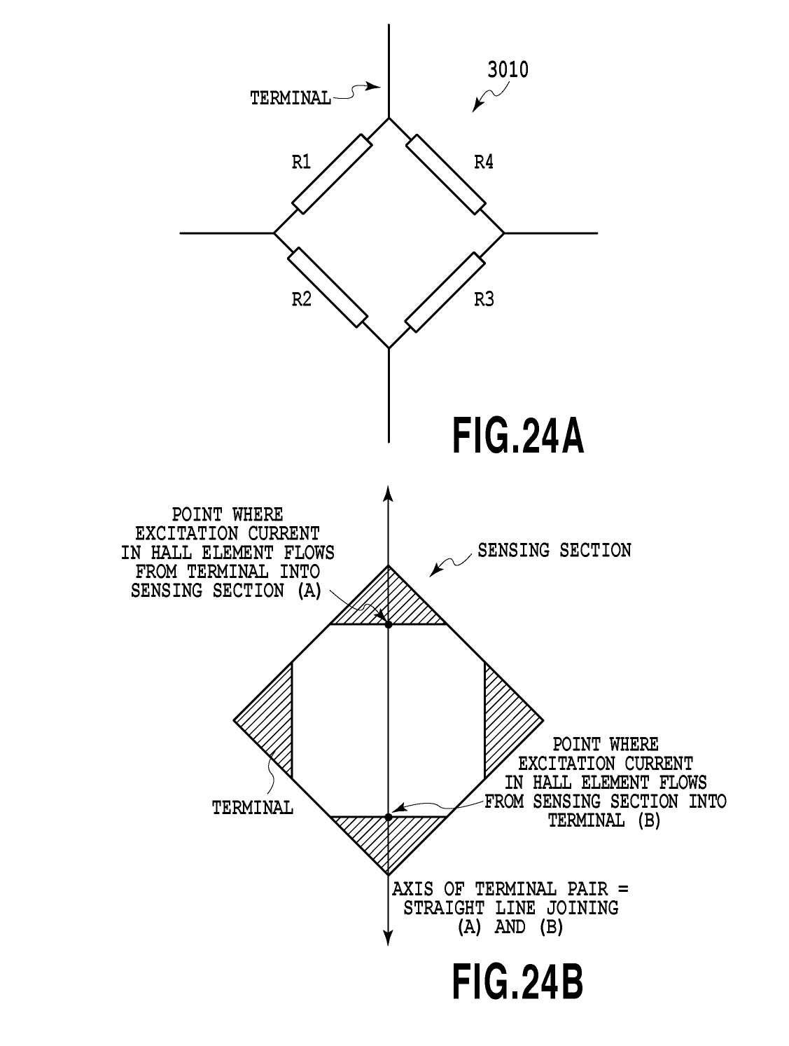

FIGS. 24A and 24B show a bridge circuit of piezoresistors included in Hall element in the magnetic-field measuring apparatus according to the present invention. FIG. 24A shows the bridge circuit, and FIG. 24B shows the shape of terminals of the Hall element. As shown in FIGS. 24A and 24B, an excitation current for the Hall element flows from a terminal into a sensing section at a point denoted by reference character A. The excitation current for the H element flows from the sensing section into the terminal at a point denoted by reference character B. The axis of the terminal pair is a straight line joining A and B together.

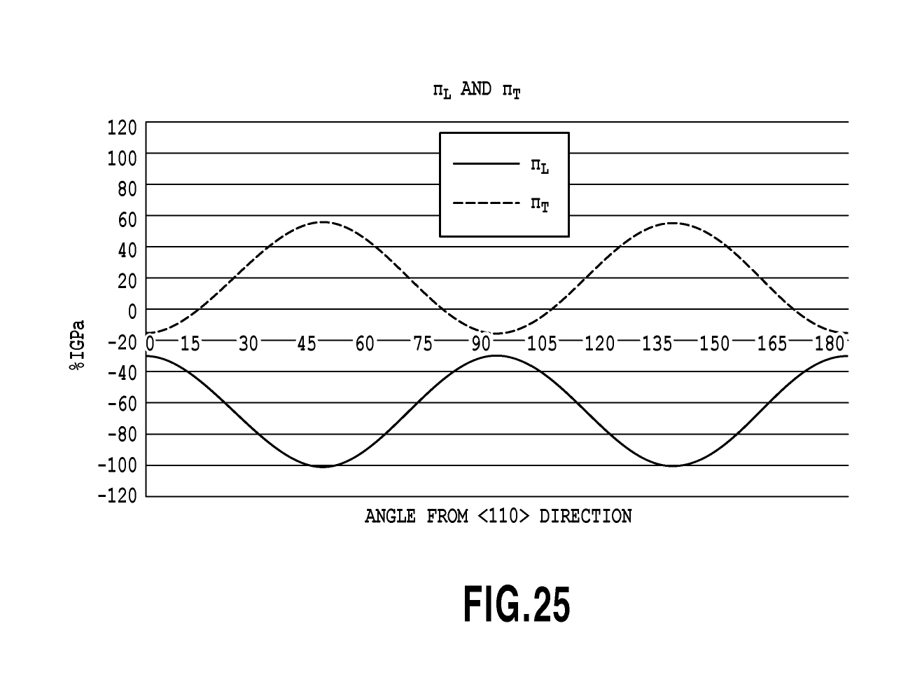

A Hall element 3010 shown in FIG. 24A is modeled by a bridge circuit including piezoresistors R1 to R4. A coefficient of piezoresistance π of the piezoresistors R1 to R4 includes a coefficient of piezoresistance π_{L}, in the longitudinal direction of the piezoresistors R1 to R4 and a coefficient of piezoresistance π_{T} for a direction (transverse direction) of the piezoresistors R1 to R4 perpendicular to the longitudinal direction. The coefficients of piezoresistance π_{L} and π_{T} change depending on a crystal orientation as shown in FIG. 25.

FIG. 25 is a diagram showing the relations between the coefficient of piezoresistance of the piezoresistors in the longitudinal direction and the coefficient of piezoresistance of the piezoresistors in the direction (transverse direction) perpendicular to the longitudinal direction, with respect to the crystal orientation <110> of an Si substrate. The difference between the coefficient of piezoresistance π_{L} in the longitudinal direction of the piezoresistors R1 to R4 and the coefficient of piezoresistance π_{T} in the transverse direction of the piezoresistors R1 to R4 decreases in a direction in which an angle to the crystal orientation <110> of the Si substrate is 0° (or 90°) and increases in a direction in which the angle to the crystal orientation <110> of the Si substrate is 45°.

Thus, in order to reduce the offset voltage caused by the difference between the coefficients of piezoresistance of the piezoresistors included in the Hall element, the direction of the piezoresistors included in the Hall element may be selectively aligned with the crystal orientation <110> of the Si substrate to reduce the difference between the coefficient of piezoresistance π_{L} and the coefficient of piezoresistance π_{T}. To allow the direction of the piezoresistors included in the Hall element to be selectively aligned with the crystal orientation <110> of the Si substrate, the direction of the terminals of the Hall element may be selectively inclined at an angle of 45° to the crystal orientation <110> of the Si substrate.

The resistances of the piezoresistors R1 to R4 change depending on the coefficients of piezoresistance π_{L} and π_{T} and also change depending on a mechanical stress σ_{L} parallel to the longitudinal direction of the piezoresistors R1 to R4 and a mechanical stress σ_{T} perpendicular to the longitudinal direction, as expressed by:

R=R0×(1+π_{L}·σ_{L}+π_{T}·σ_{T}) (18)

A piezoresistance value R0 is obtained when no mechanical stress is applied. A coefficient of piezoresistance π_{L} is intended for the longitudinal direction. A coefficient of piezoresistance π_{T} is intended for the transverse direction. A mechanical stress σ_{L} is applied to the piezoresistors in the longitudinal direction thereof. A mechanical stress σ_{T} is applied to the piezoresistors in the transverse direction thereof.

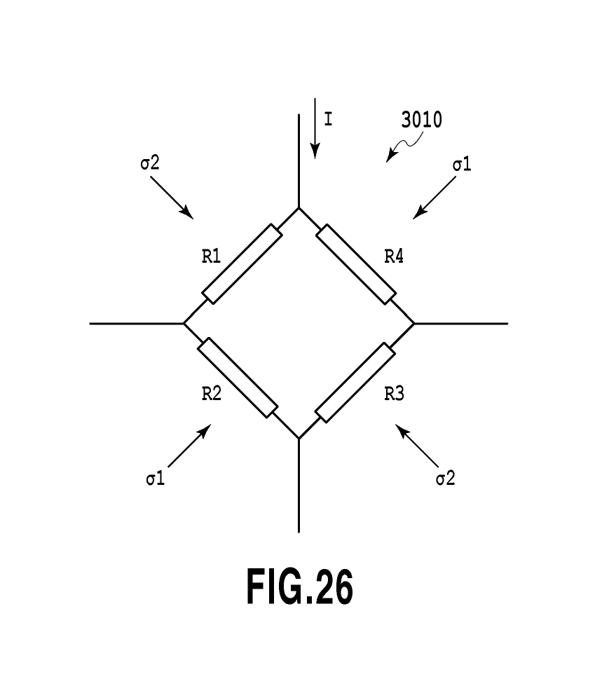

FIG. 26 is a diagram showing a bridge circuit and illustrating the relations between the mechanical stress and offset in the Hall element in the magnetic-field measuring apparatus according to the present invention. When mechanical stress is applied to each of the piezoresistors R1 to R4 in the Hall element 3010, the resistances of the piezoresistors R1 to R4 change as expressed by Expression 19. When a current I is passed through the piezoresistors R1 to R4, offset occurs as expressed by Expression 20.

$$\begin{matrix}R 1 = R 3 = R 0 \times ( 1 + {π}_{L} \cdot σ 1 + {π}_{T} \cdot σ 2 ) \\ R 2 = R 4 = R 0 \times ( 1 + {π}_{L} \cdot σ 2 + {π}_{T} \cdot σ 1 ) & ( 19 ) \\ \begin{matrix}Voffset = ( R 2 - R 3 ) \cdot I / 2 \\ = R 0 \cdot ( {π}_{L} - {π}_{T} ) \cdot ( σ 2 - σ 1 ) \cdot I / 2\end{matrix} & ( 20 )\end{matrix}$$

A mechanical stress σ1 is applied to the piezoresistors R1 and R3 in the longitudinal direction thereof (applied to the piezoresistors R2 and R4 in the transverse direction). A mechanical stress 62 is applied to the piezoresistors R2 and R4 in the longitudinal direction thereof (applied to the piezoresistors R1 and R3 in the transverse direction).

Expression 20 indicates that a reduction in the difference between π_{L} and π_{T} reduces the offset. FIG. 25 shows that the longitudinal direction of the piezoresistors corresponds to the crystal orientation <110> of the Si substrate. Thus, it may be appreciated that the mechanical stress exerted on the Hall element can be reduced by aligning the longitudinal direction of the piezoresistors included in the Hall element with the crystal orientation <110> of the Si substrate. This means that the terminals of the Hall element may be disposed at an angle of 45° to the X and Y axes, which are parallel to the longitudinal direction and transverse direction of the Si substrate, and may be disposed at an angle of 45° to the crystal orientation <110> of the Si substrate.

Furthermore, conventional Hall sensors include a combination of a Hall element and a magnetic flux concentrator. However, a difference in the coefficient of thermal expansion between the Hall element and the magnetic flux concentrator causes mechanical stress on the Hall element, leading to an offset.

The embodiments of the present invention have been clarified, by simulation, to be able to reduce the difference in mechanical stress (σ2−σ1) shown in Expression 20 by placing the Hall element in an optimum direction for the magnetic flux concentrator. Expression 20 enables the offset to be reduced.

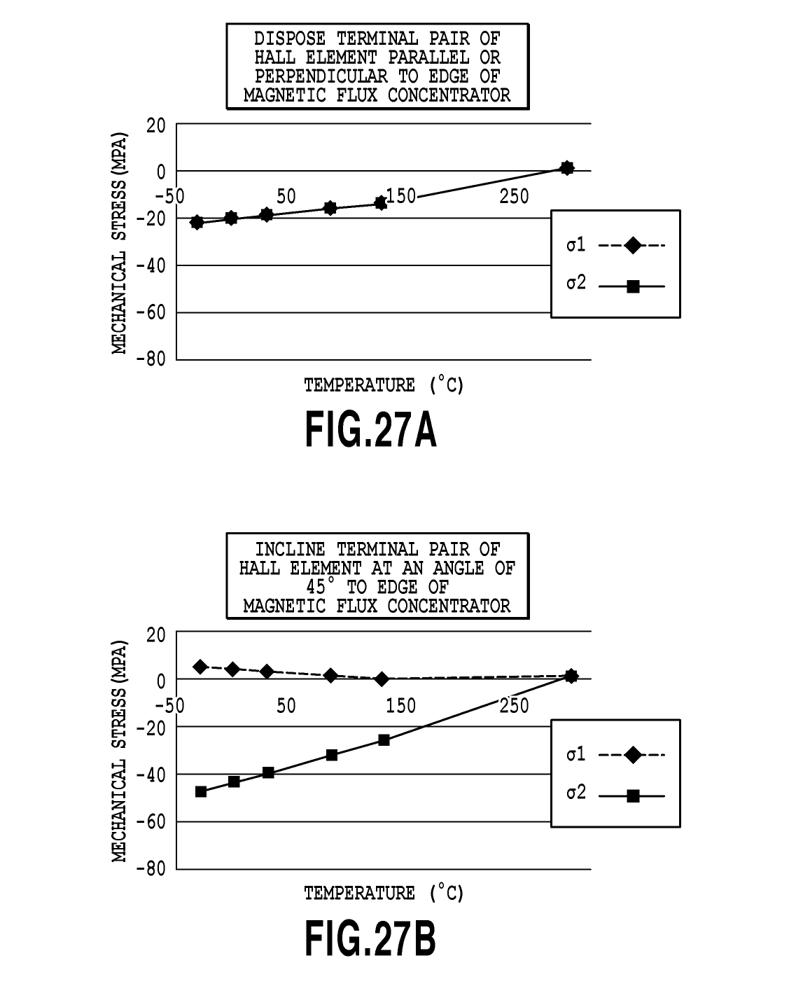

FIGS. 27A and 27B are diagrams showing the results of simulation of temperature characteristics of a first mechanical stress σ1 and a second mechanical stress σ2 observed when the terminal pair of the Hall element is disposed parallel to an edge of the magnetic flux concentrator and when the terminal pair of the Hall element is disposed at an angle of 45° to the edge of the magnetic flux concentrator. FIG. 27A shows the temperature characteristics of the first mechanical stress σ1 and the second mechanical stress σ2 observed when the terminal pair of the Hall element is disposed parallel to the edge of the magnetic flux concentrator. FIG. 27B shows the temperature characteristics of the first mechanical stress σ1 and the second mechanical stress σ2 observed when the terminal pair of the Hall element is disposed at an angle of 45′ to the edge of the magnetic flux concentrator. That is, Expression 20 indicates that the difference in mechanical stress (σ2−σ1) may be reduced in order to further decrease the offset. To achieve this, the terminal pair of the Hall element may be disposed parallel to the edge of the magnetic flux concentrator as shown in FIG. 27A.

Thus, the following are required to accomplish the object of the present invention. 1) In order to reduce an offset voltage caused by a difference between the coefficients of piezoresistance of the piezoresistors included in the Hall element, the Hall element is arranged such that the direction of the piezoresistors coincides with the crystal orientation <110> of the Si substrate, that is, such that the direction of the terminals of the Hall element is at an angle of 45° to the crystal orientation <110> of the Si substrate, so as to decrease the difference between the coefficient of piezoresistance π_{L} and the coefficient of piezoresistance π_{T}, and 2) in order to reduce an offset voltage caused by a difference in mechanical stress applied to the Hall element by the magnetic flux concentrator, the terminal pair of the Hall element needs to be disposed parallel to the edge of the magnetic flux concentrator so as to decrease the difference between the mechanical stress σ1 exerted in the longitudinal direction of one pair of opposite piezoresistors and the mechanical stress σ2 exerted in the longitudinal direction of the other pair of opposite piezoresistors.

Embodiments of the magnetic-field measuring apparatus according to the present invention will be described. First, the relations between the piezoresistors included in the Hall element and the mechanical stress applied to the Hall element will be described.

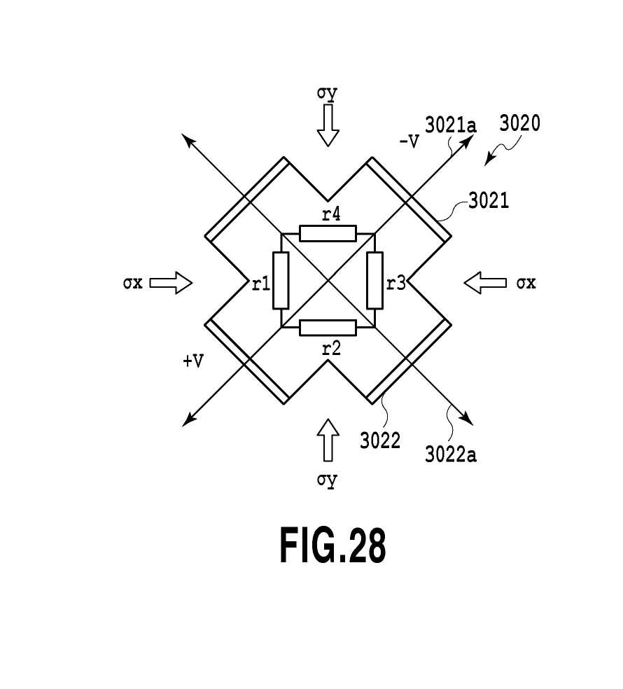

FIG. 28 is a diagram showing a bridge circuit and illustrating the relations between the mechanical stress and offset in the Hall element in the magnetic-field measuring apparatus according to the present invention. In FIG. 28, the bridge shown in FIG. 26 is inclined by an angle of 45°. As shown in FIG. 28, when mechanical stress is applied to piezoresistors r1 to r4 in a Hall element 3020, the resistances of the piezoresistors r1 to r4 change as expressed by Expression 21. When a current I is passed through the piezoresistors, an offset occurs as expressed by Expression 22.

$$\begin{matrix}r 1 = r 3 = r 0 \times ( 1 + {π}_{L} \cdot σ y + {π}_{T} \cdot σ x ) \\ r 2 = r 4 = r 0 \times ( 1 + {π}_{L} \cdot σ x + {π}_{T} \cdot σ y ) & ( 21 ) \\ \begin{matrix}Voffset = ( r 2 - r 3 ) \cdot I / 2 \\ = r 0 \cdot ( {π}_{L} - {π}_{T} ) \cdot ( σ x - σ y ) \cdot I / 2\end{matrix} & ( 22 )\end{matrix}$$

A piezoresistance value r0 is obtained when no mechanical stress is applied to the Hall element, a coefficient of piezoresistance π_{L} is intended for the longitudinal direction, and a coefficient of piezoresistance π_{T} is intended for the transverse direction, as described with reference to FIG. 26. A mechanical stress θx is exerted in the transverse direction of one pair of opposite piezoresistors r1 and r3 (the longitudinal direction of the piezoresistors r2 and r4). A mechanical stress σy is exerted in the transverse direction of the other pair of opposite piezoresistors r2 and r4 (the longitudinal direction of the piezoresistors r1 and r3). Furthermore, a first terminal pair and the axis of the first terminal pair are denoted by reference numeral 3021 and reference numeral 3021a, respectively. A second terminal pair and the axis of the second terminal pair are denoted by reference numeral 3022 and reference numeral 3022a, respectively.

### Embodiment 6

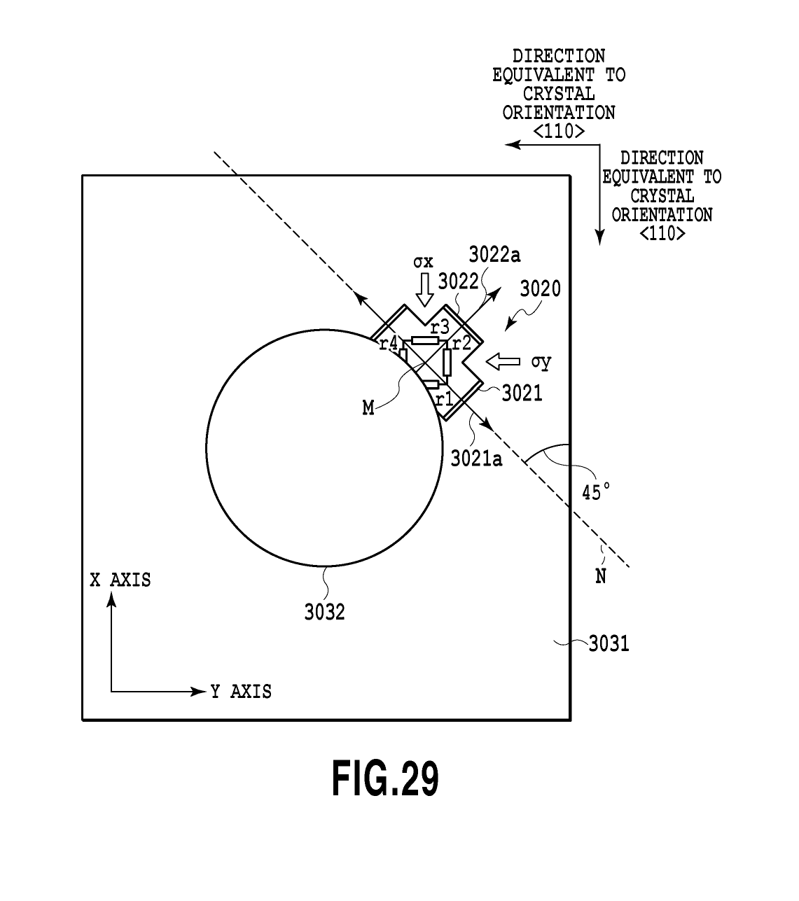

FIG. 29 is a configuration diagram illustrating Embodiment 6 of the magnetic-field measuring apparatus according to the present invention. In FIG. 29, a silicon (Si) substrate is denoted by reference numeral 3031. A magnetic flux concentrator is denoted by reference numeral 3032. The Hall element shown in FIG. 28 is placed at an end of the magnetic flux concentrator by being rotated through 45°. According to Embodiment 6, the magnetic flux concentrator overlaps the Hall element so as to substantially reach a central portion thereof.

The magnetic-field measuring apparatus according to Embodiment 6 of the present invention includes a substantially rectangular silicon substrate 3031, at least one Hall element 3020 formed on a surface of the silicon substrate 3031 and having a first terminal pair 3021 and a second terminal pair 3022 each including two terminals provided opposite each other, an axis 3021a of the first terminal pair being orthogonal to an axis 3022a of the second terminal pair, and a circular magnetic flux concentrator 3032 provided on the surface of the silicon substrate 3031.

Furthermore, the Hall element 3020 is formed on the surface of the silicon substrate 3031 such that the crystal orientations of the silicon substrate 3031 in the longitudinal direction and transverse direction thereof are equivalent to <110>, such that when the silicon substrate 3031 and the magnetic flux concentrator 3032 are viewed in plan, the axis 3021a of the first terminal pair of the Hall element 3020 is substantially parallel to a tangential direction N, on an outer edge of the magnetic flux concentrator 3032, of a tangent point between the outer edge of the magnetic flux concentrator 3032 and a minimum-radius circle centered around the center M of the Hall element 3020, serving as a circle center point, the minimum-radius circle being tangent to the outer edge of the magnetic flux concentrator 3032, and such that the axis 3021a of the first terminal pair subtends an angle of 45° to the longitudinal direction or transverse direction of the silicon substrate 3031.

The shape of the Magnetic flux concentrator 3032 is not particularly limited. However, if the Magnetic flux concentrator 3032 appears to be line-symmetric with respect to the axis 3022a of the second terminal pair, serving as a axis of symmetry, when the silicon substrate 3031 and the magnetic flux concentrator 3032 are viewed in plan, then the difference between the mechanical stress σx and the mechanical stress σy is preferably small. In the description of the present embodiment, the magnetic flux concentrator 3032 appears to be line-symmetric with respect to the axis 3022a of the second terminal pair, serving as an axis of symmetry, when the silicon substrate 3031 and the magnetic flux concentrator 3032 are viewed in plan.

The magnetic-field measuring apparatus according to Embodiment 6 of the present invention includes a substrate 3031 with a predetermined crystal orientation, a Hall element 3020 provided on the substrate 3031, and a magnetic flux concentrator 3032 provided on the Hall element 3032 so that the Hall element 3020 is located at an end thereof, the magnetic flux concentrator 3032 having a magnetic amplification function. The Hall element has a first terminal pair 3021 and a second terminal pair 3022 provided opposite each other and each including two terminals. Piezoresistors r1 to r4 shown between the terminals of the terminal pairs so as to overlap the terminal pairs correspond to an equivalent circuit that models a Hall element.

Furthermore, in order to reduce an offset voltage caused by a difference between the coefficients of piezoresistance π_{L} and π_{T} of the piezoresistors r1 to r4, the Hall element 3020 is disposed such that the terminal pairs of the Hall element are inclined at an angle of 45° to a predetermined crystal orientation of the substrate 3031, so as to decrease the difference between the coefficient of piezoresistance π_{L} in the longitudinal direction of the piezoresistors r1 to r4 between the terminal pairs and the coefficient of piezoresistance π_{T} in the transverse direction of the piezoresistors r1 to r5. Furthermore, in order to reduce an offset voltage caused by a difference between the mechanical stresses ax and ay exerted by the magnetic flux concentrator 3032, the Hall element 3020 is disposed parallel to an edge of the magnetic flux concentrator 3032 so as to decrease the difference between mechanical stress σx and the mechanical stress σy. This means that the terminals of the Hall element may be disposed at an angle of 45° to the X and Y axis directions parallel to the longitudinal direction and transverse direction of the Si substrate and that the terminals of the Hall element may be disposed at an angle of 45° to the crystal orientation <110> of the Si substrate.

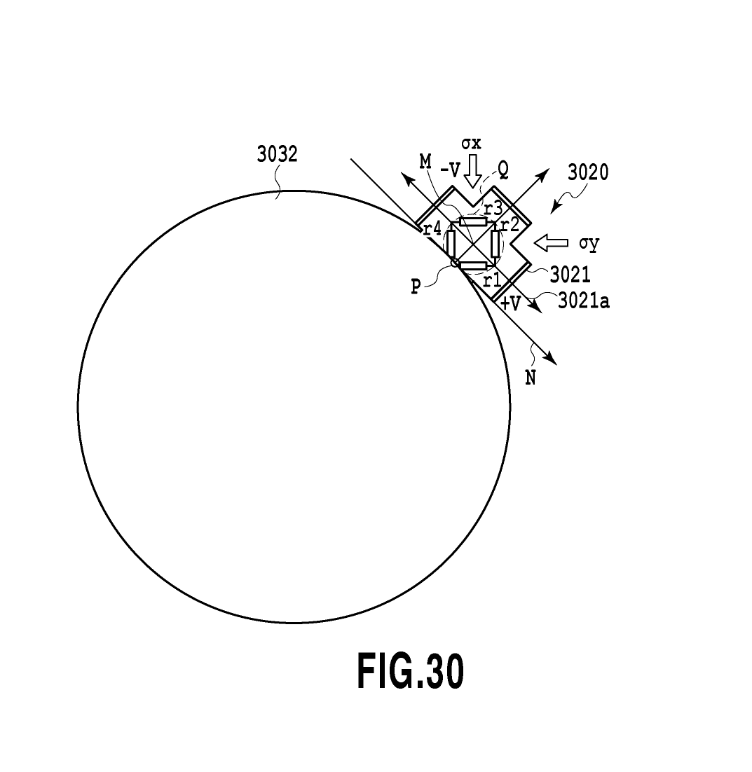

FIG. 30 is a configuration diagram illustrating the tangential direction in FIG. 29 and showing a variation of Embodiment 6. FIG. 30 is a diagram illustrating another example in which the axis 3021a of the first terminal pair of the Hall element 3020 is substantially parallel to the tangential direction N, on the outer edge of the magnetic flux concentrator 3032, of the tangent point between the outer edge of the magnetic flux concentrator 3032 and the minimum-radius circle centered around the center M of the Hall element 3020, serving as a circle center point, the minimum-radius circle being tangent to the outer edge of the magnetic flux concentrator 3032. In FIG. 30, the Hall element and the magnetic flux concentrator partly overlap.

In FIG. 30, the tangent point at which the minimum-radius circle is tangent to the outer edge of the magnetic flux concentrator 32 is denoted by reference character P. The minimum-radius circle centered around the center N of the Hall element 3020, serving as a circle center point, the minimum-radius circle being tangent to the outer edge of the magnetic flux concentrator is denoted by reference character Q.

This configuration enables implementation of a magnetic-field measuring apparatus that takes the positional relations between the Hall element and the substrate and the magnetic flux concentrator into account to reduce the offset voltage caused by the difference in the coefficient of piezoresistance of the piezoresistors included in the Hall element and the offset voltage caused by the difference in the mechanical stress applied to the Hall element by the magnetic flux concentrator.

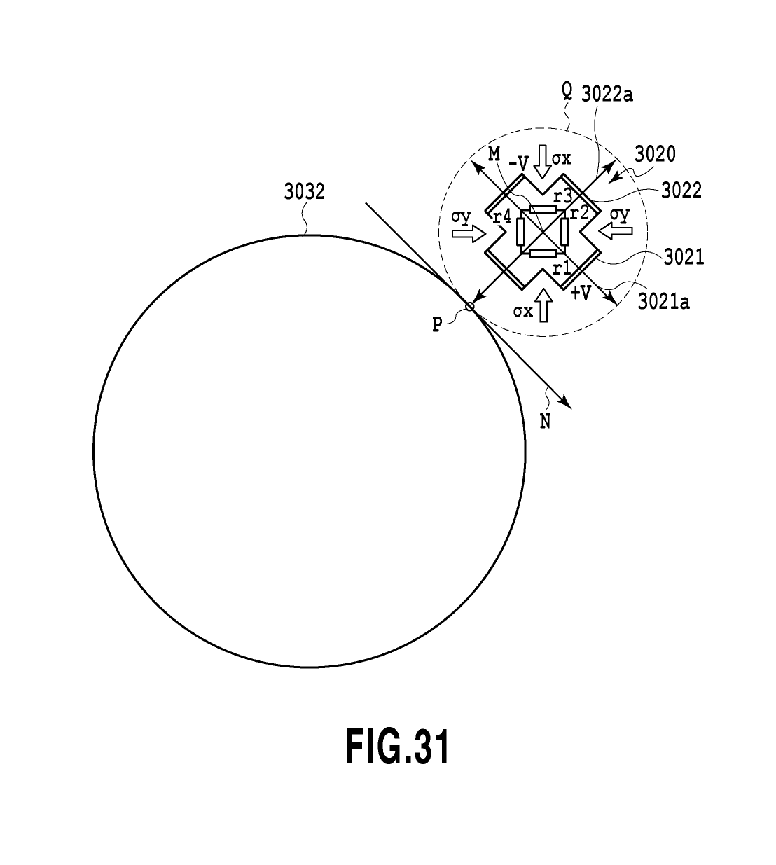

FIG. 31 is a configuration diagram showing another variation of Embodiment 6 shown in FIG. 29, wherein the Hall element does not overlap the magnetic flux concentrator. In FIG. 30, the Hall element 3020 partly overlaps the magnetic flux concentrator 3032. In FIG. 31, the Hall element 3020 does not overlap the magnetic flux concentrator 3032.

Even in this case, the positional relations between the Hall element and the magnetic flux concentrator according to Embodiment 6 shown in FIG. 29 are met. Thus, a magnetic-field measuring apparatus configured to reduce the offset voltage can be implemented.

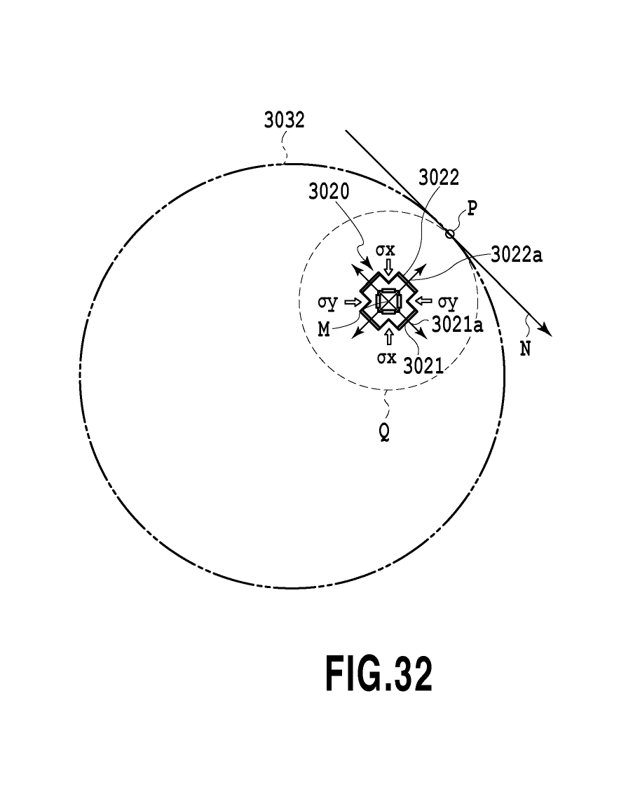

FIG. 32 is a configuration diagram showing further another variation of Embodiment 6 shown in FIG. 29. In FIG. 31, the Hall element 3020 does not overlap the magnetic flux concentrator 3032. However, in FIG. 32, the Hall element 3032 is disposed inside the magnetic flux concentrator 3032. That is, a minimum-radius circle Q centered around the center M of the Hall element 3020, serving as a circle center point, the minimum-radius circle being tangent to the outer edge of the magnetic flux concentrator 3032, is inscribed inside the outer edge of the circular magnetic flux concentrator. Thus, the Hall element 3020 completely overlaps the magnetic flux concentrator 3032.

Even in such a case, the positional relations between the Hall element and the magnetic flux concentrator according to Embodiment 6 shown in FIG. 29 are met. Thus, a magnetic-field measuring apparatus configured to reduce the offset voltage can be implemented.

This configuration enables implementation of a magnetic-field measuring apparatus that takes the positional relations between the Hall element and the substrate and the magnetic flux concentrator into account to reduce the offset voltage caused by the difference between the coefficient of piezoresistance in the longitudinal direction of the piezoresistors of the Hall element modeled by a Wheatstone bridge circuit of piezoresistance elements and the coefficient of piezoresistance in the transverse direction of the piezoresistors and also to reduce the offset voltage caused by the difference in the mechanical stress applied to the Hall element by the magnetic flux concentrator.

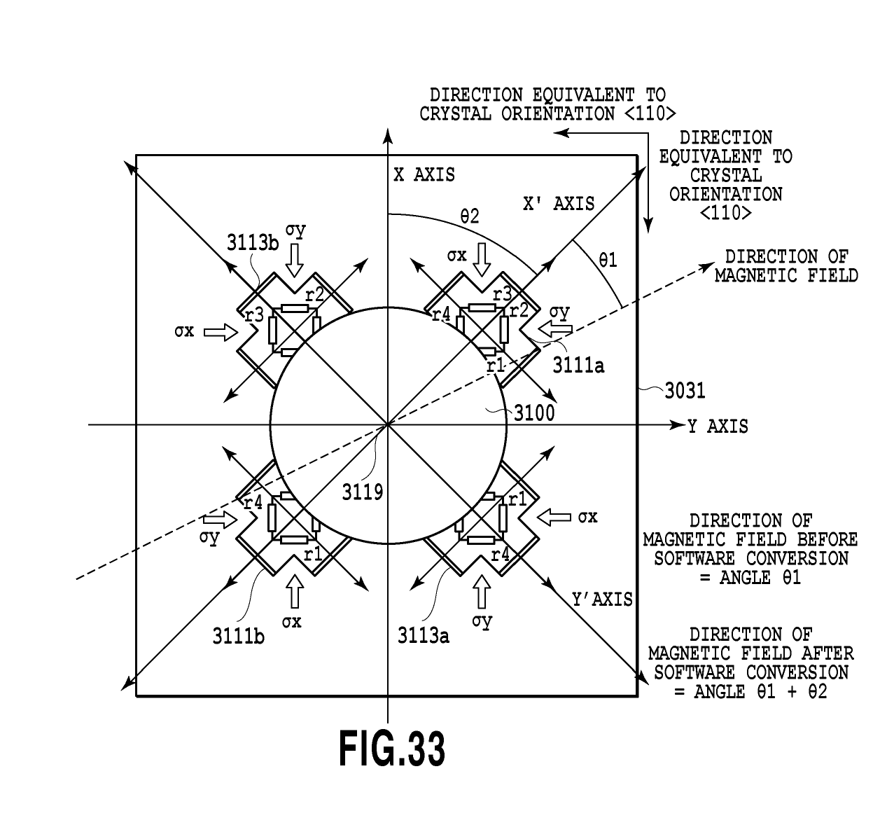

FIG. 33 is a diagram illustrating that arithmetic processing is carried out to convert an output from the Hall element into an output based on a direction parallel to sides of the silicon substrate. FIG. 33 also illustrates a magnetic-field direction measuring apparatus using the magnetic-field measuring apparatus according to the present invention.

A disc-like magnetic flux concentrator 3100 is installed in a central portion of a surface of the silicon substrate 3031. On the circumference of the magnetic flux concentrator 3100, X′ axis Hall elements 3111a and 3111b are installed point-symmetrically with respect to a circle center point 3119, and Y′ axis Hall elements 3113a and 3113b are also installed point-symmetrically with respect to the circle center point 3119. That is, two line segments joining the X′ axis Hall elements 3111 together and the Y′ axis Hall elements 3113 together, respectively, intersect at the circle center point 3119. Moreover, the distance from the circle center point 3119 to the X′ axis Hail element 3111a is equal to the distance from the circle center point 3119 to the X′ axis Hall element 3111b. The distance from the circle center point 3119 to the Y′ axis Hall element 3113a is equal to the distance from the circle center point 3119 to the Y′ axis Hall element 3113b. The direction from the X′ axis Hall element 3111b toward the X′ axis Hall element 3111a and the direction from the Y′ axis Hall element 3113b toward the Y′ axis Hall element 3113a are defined to be a positive direction of the X′ axis and a positive direction of the Y′ axis, respectively.

Now, a method for detecting the rotation angle will be described. When a magnetic field (shown by a dotted arrow in FIG. 33) is applied as shown in FIG. 33, output differential voltages V(X′+), V(X′−), V(Y′+), and V(Y′−) from Hall elements 3111a, 3111b, 3113a, and 3113b are such sine wave voltages and cosine wave voltages as expressed by:

V(X′+)=A×cos θ1

V(X′−)=−A×cos θ1

V(Y′+)=A×sin θ1

V(Y′−)=−A×sin θ1 (23).

Here, a proportional constant A is used, and a counterclockwise angle (magnetic-field application angle) θ1 is subtended between the X′ axis direction and the direction of a magnetic field (a dotted arrow in FIG. 33). The differences between the output voltages are determined as expressed by Expression (24) to derive output voltages Vx′ and Vy′ in the X′ axis direction and the Y′ axis direction.

Vx′=V1(X′+)−V2(X′−)=2A×cos θ1

Vy′=V1(Y′+)−V2(Y′−)=2A×sin θ1 (24)

The output voltages Vx′ and Vy′ generated are used to calculate a relative angle.

Signal processing is carried out. A magnetic-field application angle θ1 can be calculated by carrying out a division as expressed by Expression (25) to determine an arc tangent.

tan θ1=Vy′/Vx′

∴θ1=arctan(Vy′/Vx′) (25)

The magnetic-field direction measuring apparatus using the magnetic-field measuring apparatus according to the present invention converts the calculated magnetic-field application angle θ1 into an angle based on the longitudinal direction of the Si substrate (a direction equivalent to the crystal orientation <110>). That is, when the longitudinal direction of the Si substrate is defined to be the X axis direction and an angle θ2 is defined to be subtended between the X axis direction and the X′ axis direction, the magnetic-field direction measuring apparatus according to the present invention calculates θ1+θ2 to obtain a magnetic-field application angle and converts the magnetic-field application angle into an angle based on the longitudinal direction of the Si substrate. A method for converting the magnetic-field application angle is not particularly limited, but preferably involves arithmetic processing (software conversion).

Convenience for users is improved by making settings that allow the angle θ1 to be subjected to the arithmetic processing (software conversion) and converted into the angle θ1+θ2, that is, settings that allow the basis for the magnetic-field application angle to be converted into the longitudinal direction of the Si substrate (a direction equivalent to the crystal orientation <110>). The present embodiment defines the longitudinal direction of the Si substrate to be the X axis direction. However, the transverse direction may be defined to be the X axis direction.

### Embodiment 7

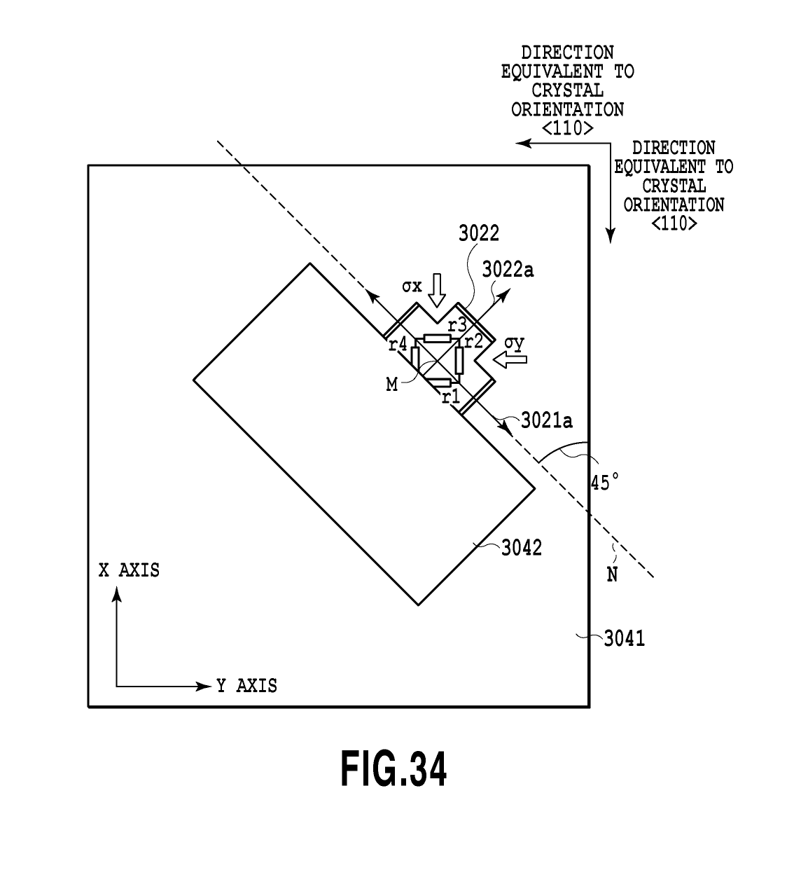

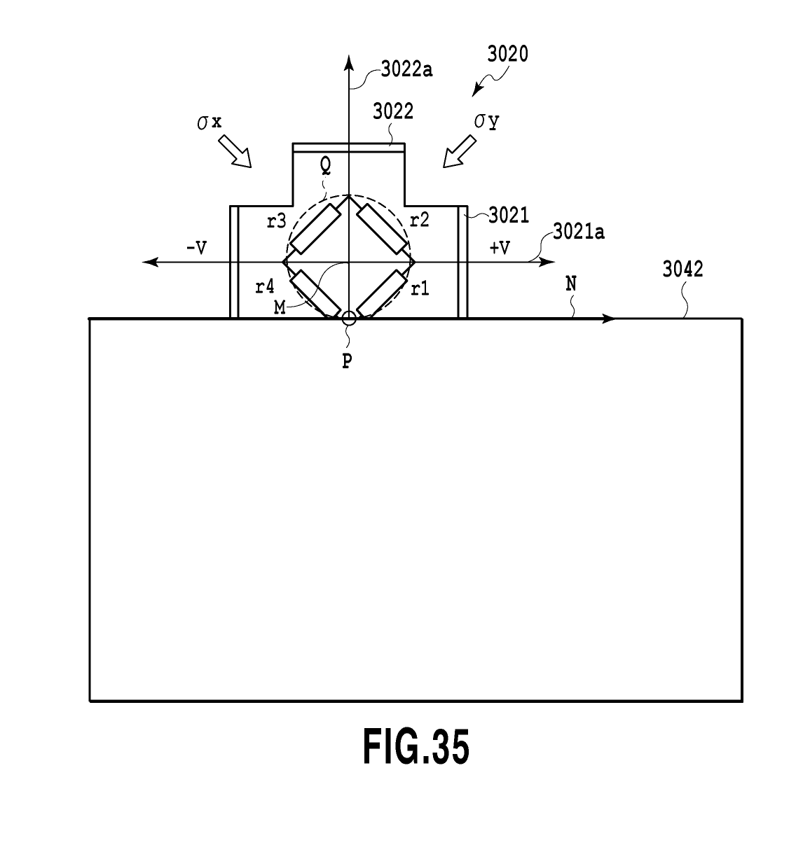

FIG. 34 is a configuration diagram illustrating Embodiment 7 of the magnetic-field measuring apparatus according to the present invention. FIG. 35 is a diagram illustrating a tangential direction in FIG. 34. In FIGS. 34 and 35, a silicon (Si) substrate is denoted by reference numeral 3041. A magnetic flux concentrator is denoted by reference numeral 3042. The configuration of the Hall element is similar to the configuration shown in FIG. 29. Embodiment 7 is different from Embodiment 6 in that the magnetic flux concentrator in Embodiment 7 is a rectangle.

The magnetic-field measuring apparatus according to Embodiment 7 of the present invention includes a substantially rectangular silicon substrate 3041, at least one Hall element 3020 provided on a surface of the silicon substrate 3041 and having a first terminal pair 3021 and a second terminal pair 3022 each including two terminals provided opposite each other, an axis 3021a of the first terminal pair being orthogonal to an axis 3022a of the second terminal pair, and a substantia rectangular magnetic flux concentrator 3042 provided on the surface of the silicon substrate 3041.

Furthermore, the Hall element 3020 is formed on the surface of the silicon substrate 3041 such that the crystal orientations of the silicon substrate 3041 in the longitudinal direction and transverse direction thereof are equivalent to <110>, such that when the silicon substrate 3041 and the magnetic flux concentrator 3042 are viewed in plan, the axis 3021a of the first terminal pair of the Hall element 3020 is substantially parallel to a tangential direction N, on an outer edge of the magnetic flux concentrator 3042, of a tangent point P between the outer edge of the magnetic flux concentrator 3042 and a minimum-radius circle Q centered around the center M of the Hall element 3020, serving as a circle center point, the minimum-radius circle being tangent to the outer edge of the magnetic flux concentrator 3042, and such that the axis 3021a of the first terminal pair subtends an angle of 45° to the longitudinal direction or transverse direction of the silicon substrate 3041.

The magnetic flux concentrator 3042 may be shaped like a square. This means that the terminals of the Hall element may be disposed at an angle of 45° to the X and Y axis directions parallel to the longitudinal direction and transverse direction of the Si substrate and that the terminals of the Hall element may be disposed at an angle of 45° to the crystal orientation <110> of the Si substrate.

This configuration enables implementation of a magnetic-field measuring apparatus that takes the positional relation between the Hall element and the substrate and the magnetic flux concentrator into account to reduce an offset voltage caused by the difference between the coefficient of piezoresistance in the longitudinal direction of the piezoresistors of the Hall element modeled by a Wheatstone bridge circuit of piezoresistance elements and the coefficient of piezoresistance in the transverse direction of the piezoresistors and also to reduce an offset voltage caused by the difference in the mechanical stress applied to the Hall element by the magnetic flux concentrator.

### Embodiment 8

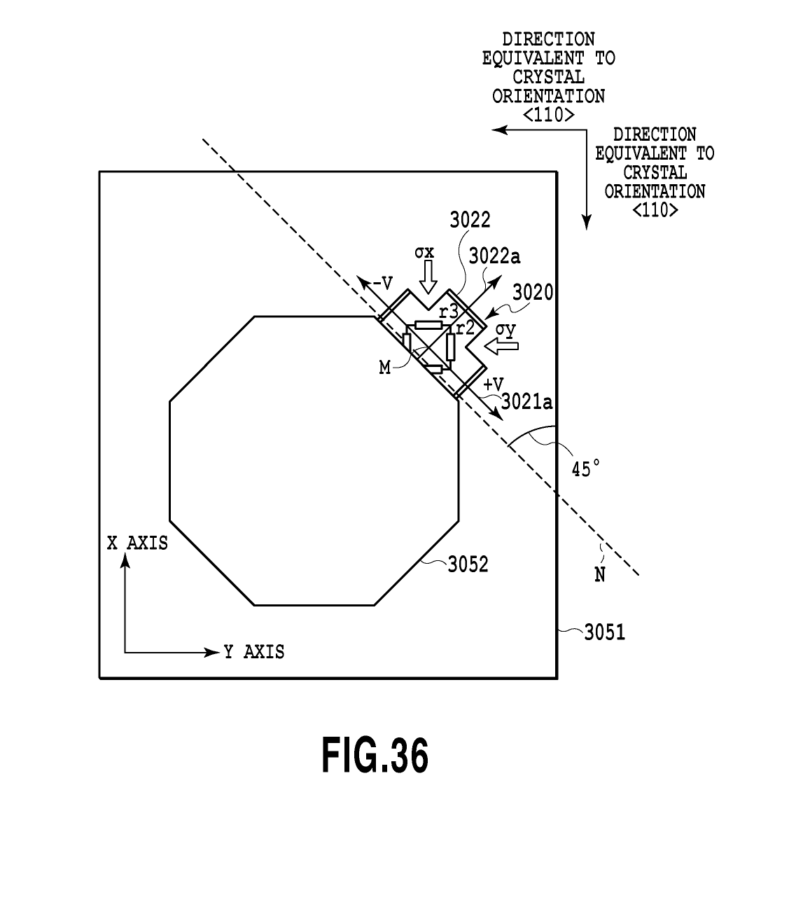

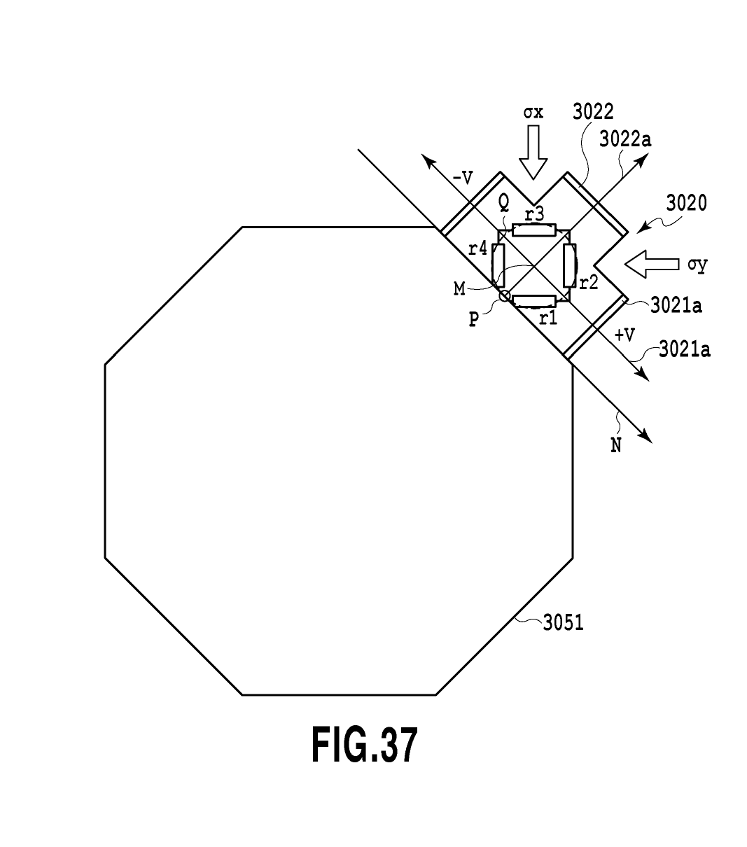

FIG. 36 is a configuration diagram illustrating Embodiment 8 of the magnetic-field measuring apparatus according to the present invention. FIG. 37 is a diagram illustrating a tangential direction in FIG. 36. In FIGS. 36 and 37, a silicon (Si) substrate is denoted by reference numeral 3051. A magnetic flux concentrator is denoted by reference numeral 3052. The configuration of the Hall element is similar to the configuration shown in FIG. 29. Embodiment 8 is different from Embodiment 6 in that the magnetic flux concentrator in Embodiment 8 is shaped like a polygon.

The magnetic-field measuring apparatus according to Embodiment 8 of the present invention includes a substantially rectangular silicon substrate 3051, at least one Hall element 3020 provided on a surface of the silicon substrate 3051 and having a first terminal pair 3021 and a second terminal pair 3022 each including two terminals provided opposite each other, an axis 3021a of the first terminal pair being orthogonal to an axis 3022a of the second terminal pair, and a substantial rectangular magnetic flux concentrator 3052 provided on the surface of the silicon substrate 3051.

Furthermore, the Hall element 3020 is formed on the surface of the silicon substrate 3051 such that the crystal orientations of the silicon substrate 3051 in the longitudinal direction and transverse direction thereof are equivalent to <110>, such that when the silicon substrate 3051 and the magnetic flux concentrator 3052 are viewed in plan, the axis 3021a of the first terminal pair of the Hall element 3020 is substantially parallel to a tangential direction N, on an outer edge of the magnetic flux concentrator 3052, of a tangent point P between the outer edge of the magnetic flux concentrator 3052 and a minimum-radius circle Q centered around the center N of the Hall element 3020, serving as a circle center point, the minimum-radius circle being tangent to the outer edge of the magnetic flux concentrator 3052, and such that the axis 3021a of the first terminal pair subtends an angle of 45° to the longitudinal direction or transverse direction of the silicon substrate 3051.

This means that the terminals of the Hall element may be disposed at an angle of 45° to the X and Y axis directions parallel to the longitudinal direction and transverse direction of the Si substrate and that the terminals of the Hall element may be disposed at an angle of 45° to the crystal orientation <110> of the Si substrate.

This configuration enables implementation of a magnetic-field measuring apparatus that takes the positional relation between the Hall element and the substrate and the magnetic flux concentrator into account to reduce an offset voltage caused by the difference between the coefficient of piezoresistance in the longitudinal direction of the piezoresistors of the Hall element modeled by a Wheatstone bridge circuit of piezoresistance elements and the coefficient of piezoresistance in the transverse direction of the piezoresistors and also to reduce an offset voltage caused by the difference in the mechanical stress applied to the Hall element by the magnetic flux concentrator.

While the present invention has been described with reference to exemplary embodiments, it is to be understood that the invention is not limited to the disclosed exemplary embodiments. The scope of the following claims is to be accorded the broadest interpretation so as to encompass all such modifications and equivalent structures and functions.

What is claimed is:

1. A magnetic-field direction measuring apparatus comprising:
a substantially rectangular substrate; and
at least one first magnetic field sensor and at least one second magnetic field sensor disposed substantially on a circumference centered around a predetermined point on a surface of the substrate serving as a circle center point,
the first magnetic field sensor detecting a magnetic component in a first direction, the second magnetic field sensor detecting a magnetic component in a second direction different from the first direction,
the magnetic-field direction measuring apparatus measuring a direction of a magnetic field based on intensities of output signals from the first magnetic field sensor and the second magnetic field sensor,
wherein the first magnetic field sensor and the second magnetic field sensor are positioned line-symmetrically with respect to a straight line on the surface of the substrate which is parallel to a longitudinal direction of the substrate or a transverse direction of the substrate and which serves as an axis of symmetry.

2. The magnetic-field direction measuring apparatus according to claim 1, wherein the first magnetic field sensor and the second magnetic field sensor are positioned line-symmetrically with respect to a straight line which is parallel to the longitudinal direction of the substrate or the transverse direction of the substrate and which passes through a center of the surface of the substrate, the straight line serving as an axis of symmetry.

3. The magnetic-field direction measuring apparatus according to claim 1, wherein the first magnetic field sensor and the second magnetic field sensor are positioned by rotating one of the first magnetic field sensor and the second magnetic field sensor through 90° around the circle center point with respect to the other of the first magnetic field sensor and the second magnetic field sensor.

4. The magnetic-field direction measuring apparatus according to claim 1, further comprising a third magnetic field sensor positioned to have a point-symmetric relation with the first magnetic field sensor with respect to the circle center point and a fourth magnetic field sensor positioned to have a point-symmetric relation with the second magnetic field sensor with respect to the circle center point.

5. The magnetic-field direction measuring apparatus according to claim 1, wherein arithmetic processing is carried out to convert a direction of the magnetic field into an output based on a direction parallel to the longitudinal direction of the substrate or the transverse direction of the substrate.

6. The magnetic-field direction measuring apparatus according to claim 1, wherein a ratio of a length of the substrate in the longitudinal direction to a length of the substrate in the transverse direction is 1.3 or more.

7. A rotation angle measuring apparatus comprising:
a substantially rectangular substrate;
a rotator comprising a rotation axis perpendicular to a surface of the substrate and generating a magnetic field; and
at least one first magnetic field sensor and at least one second magnetic field sensor disposed on a surface of the substrate and substantially on a circumference centered around a position of an intersection point between the surface of the substrate and the rotation axis, the position serving as a circle center point,
the first magnetic field sensor detecting a magnetic component in a first direction, the second magnetic field sensor detecting a magnetic component in a second direction different from the first direction,
the rotation angle measuring apparatus measuring a rotation angle of the rotator based on intensities of output signals from the first magnetic field sensor and the second magnetic field sensor,
wherein the first magnetic field sensor and the second magnetic field sensor are positioned line-symmetrically with respect to a straight line on the surface of the substrate which is parallel to a longitudinal direction of the substrate or a transverse direction of the substrate, the straight line serving as an axis of symmetry.

8. The rotation angle measuring apparatus according to claim 7, wherein the first magnetic field sensor and the second magnetic field sensor are positioned line-symmetrically with respect to a straight line which is parallel to the longitudinal direction of the substrate or the transverse direction of the substrate and which passes through a center of the surface of the substrate, the straight line serving as an axis of symmetry.

9. The rotation angle measuring apparatus according to claim 7, wherein arithmetic processing is carried out to convert a rotation angle of the rotator into an output based on a direction parallel to the longitudinal direction of the substrate or the transverse direction of the substrate.

10. The rotation angle measuring apparatus according to claim 7, wherein a ratio of a length of the substrate in the longitudinal direction to a length of the substrate in the transverse direction is 1.3 or more.

11. A magnetic-field measuring apparatus comprising:
a substantially rectangular silicon substrate;
at least one Hall element formed on a surface of the silicon substrate including a first terminal pair and a second terminal pair wherein each terminal pair has two terminals provided at opposite directions, and an axis of the first terminal pair is orthogonal to an axis of the second terminal pair; and
a magnetic flux concentrator provided on the surface of the silicon substrate,
wherein crystal orientations of the silicon substrate in a longitudinal direction and a transverse direction thereof are equivalent to <110>,
wherein when the silicon substrate and the magnetic flux concentrator are viewed in plane, the axis of the first terminal pair of the Hall element is parallel to a tangential direction, on an outer edge of the magnetic flux concentrator, of a tangent point between the outer edge of the magnetic flux concentrator and a minimum-radius circle centered around a center of the Hall element serving as a circle center point, and
wherein the Hall element is formed on the surface of the silicon substrate in such a manner that the axis of the first terminal pair subtends an angle of 45° to the longitudinal direction or the transverse direction of the silicon substrate.

12. The magnetic-field measuring apparatus according to claim 11, wherein the magnetic-field measuring apparatus takes into account a relation for the offset voltage generated in the Hall element expressed by:
Voffset=r₀·(π_{L}−π_{T})·(σx−σy)·I/2.
a current I flows through the Hall element, a piezoresistance value r₀ is obtained when no mechanical stress is applied to the Hall element, a coefficient of piezoresistance π_{L} is intended for the longitudinal direction, a coefficient of piezoresistance π_{T} is intended for the transverse direction, and one of mechanical stresses σx and σy is applied to piezoresistors in a longitudinal direction thereof, and the other is applied to the piezoresistors in a transverse direction thereof, and
in order to reduce an offset voltage caused by a difference in a coefficient of piezoresistance of the piezoresistor, the Hall element is disposed to decrease a difference between the coefficient of piezoresistance in the longitudinal direction of the piezoresistors between the terminal pairs and the coefficient of piezoresistance in the transverse direction of the piezoresistors, and in order to reduce an offset voltage caused by a difference in mechanical stress applied by the magnetic flux concentrator, the Hall element is disposed parallel to an edge of the magnetic flux concentrator to decrease a difference between a mechanical stress applied to the piezoresistors in the longitudinal direction thereof and a mechanical stress applied to the piezoresistors in the transverse direction thereof.

13. The magnetic-field measuring apparatus according to claim 11, wherein when the silicon substrate and the magnetic flux concentrator are viewed in plane, the magnetic flux concentrator appears to be shaped line-symmetrically with respect to the axis of the second terminal pair serving as an axis of symmetry.

14. The magnetic-field measuring apparatus according to claim 11, wherein the magnetic flux concentrator is shaped like one of a circle, a polygon, an ellipse, and a semicircle.

15. The magnetic-field measuring apparatus according to claim 11, wherein arithmetic processing is carried out to convert an output from the Hall element into an output based on a direction parallel to the longitudinal direction of the substrate or the transverse direction of the substrate.

16. A magnetic-field measuring apparatus comprising:
a substrate with a predetermined crystal orientation;
a Hall element provided on the substrate; and
a magnetic flux concentrator provided on the Hall element in such a manner that the Hall element is disposed at an end of the magnetic flux concentrator,
wherein the Hall element has a first terminal pair and a second terminal pair each including two terminals provided opposite each other,
wherein the magnetic-field measuring apparatus takes into account a relation for an offset voltage generated in the Hall element, the relation being expressed by:
Voffset=r₀·(π_{L}−π_{T})·(σx−σy)·I/2.
a current flows through the Hall element, a piezoresistance value r₀ is obtained when no mechanical stress is applied to the Hall element, a coefficient of piezoresistance π_{L} is intended for a longitudinal direction, a coefficient of piezoresistance π_{T} is intended for a transverse direction, and one of mechanical stresses σx and σy is applied to piezoresistors in the longitudinal direction thereof, and the other is applied to the piezoresistors in the transverse direction thereof,
wherein in order to reduce an offset voltage caused by a difference in the coefficient of piezoresistance of the piezoresistor, the Hall element is disposed to decrease a difference between the coefficient of piezoresistance in t longitudinal direction of the piezoresistors between the terminal pairs and the coefficient of piezoresistance in the transverse direction of the piezoresistors, and
wherein in order to reduce an offset voltage caused by a difference in mechanical stress applied by the Magnetic flux concentrator, the Hall element is disposed parallel to an edge of the Magnetic flux concentrator to decrease a difference between a mechanical stress applied to the piezoresistors in the longitudinal direction thereof and a mechanical stress applied to the piezoresistors in the transverse direction thereof.
